(19) United States
(12) Patent Application Publication
(10) Pub. No.: US 2024/0297194 A1
(43) Pub. Date: Sep. 5, 2024

(54) STAGED BIASED DEEP TRENCH ISOLATION (DTI) STRUCTURE FOR HIGH FULL WELL CAPACITY (FWC)

(71) Applicant: OMNIVISION TECHNOLOGIES, INC., Santa Clara, CA (US)

(72) Inventors: Qin Wang, San Jose, CA (US); Yu Jin, Lawrence Township, NJ (US)

(21) Appl. No.: 18/177,684

(22) Filed: Mar. 2, 2023

(51) Int. Cl. H01L 27/146; H04N 25/78

(52) U.S. Cl. CPC H01L 27/1463; H01L 27/14636; H01L 27/14643; H01L 27/14683; H04N 25/78

(57) ABSTRACT

A pixel cell includes a front deep trench isolation (FDTI) structure extending into a semiconductor material from a frontside. The FDTI structure isolates a first region of the semiconductor material from a second region of the semiconductor material. The FDTI structure includes a first conductive material coupled to receive a first bias voltage. A back deep trench isolation (BDTI) extends into the semiconductor material from a backside. The BDTI structure isolates the first region of the semiconductor material from the second region of the semiconductor material. The BDTI structure includes a second conductive material coupled to receive a second bias voltage. The FDTI structure and BDTI structure are at least partially aligned in a depthwise direction of the semiconductor material. A photodiode is disposed in the first region of the semiconductor material proximate to at least a portion of the FDTI structure and a portion of the BDTI structure.

### TECHNICAL FIELD

The present invention relates generally to semiconductor processing. More specifically, examples of the present invention are related to semiconductor processing of image sensor pixel cells.

### BACKGROUND

An image capture device includes an image sensor and an imaging lens. The imaging lens focuses light onto the image sensor to form an image, and the image sensor converts the light into electric signals. The electric signals are output from the image capture device to other components of a host electronic system. The electronic system may be, for example, a mobile phone, a computer, a digital camera or a medical device.

There is a continuing demand to reduce the size of image sensors, which results in the smaller pixel cells for an image sensor with the same resolution. As the sizes of pixel cells continue to decease, the issue of crosstalk and unwanted signal transfer between adjacent pixel cells continues to become a growing challenge. Furthermore, as image sensors are miniaturized, the pixel cells contained therein suffer from increased dark current rates.

### BRIEF DESCRIPTION OF THE DRAWINGS

Non-limiting and non-exhaustive embodiments of the present invention are described with reference to the following figures, wherein like reference numerals refer to like parts throughout the various views unless otherwise specified.

FIG. 1 depicts a cross section view illustrating two adjacent pixel cells with a frontside surface and a backside surface.

FIG. 2A shows a schematic illustrating one example of pixel cell in an example pixel array having frontside deep trench isolation (FDTI) structures and backside deep trench isolation (BDTI) structures.

FIG. 2B shows an example timing diagram for a pixel cell.

FIG. 2C illustrates an example of an imaging system including a pixel array with pixel cells having deep trench isolation structures.

FIG. 3 shows an example of a plot of electric potential in volts vs. position in depth in a photodiode from the backside to the frontside.

FIG. 4 shows four example plots of voltage potential vs. location from the backside to the frontside of a photodiode

FIG. 5 shows a schematic cross-section of two photodiodes and a plot of voltage potential vs. depth with the depths of the illustrated photodiodes aligned with the plot.

FIG. 6 shows an example method of biasing FDTI and BDTI structures modulating the electric potential of a photodiode in accordance to an operation of the photodiode.

FIG. 7 shows examples of various views of a group of photodiodes.

FIG. 8 shows an example diagram of a four-cell pixel unit.

FIG. 9A shows an example process for producing FDTI structures.

FIG. 9B shows an example process for producing BDTI structures.

FIG. 10A shows an example of FDTI and BDTI electrical connections to a pixel array.

FIG. 10B shows another example of FDTI and BDTI electrical connections to a pixel array.

FIG. 11A shows another process for producing FDTI structures.

FIG. 11B shows a continuation of the process for producing FDTI structures in FIG. 11A.

FIG. 11C shows a continuation of the process for producing FDTI structures in FIG. 11B.

FIG. 12 shows photodiodes with a silicon substrate interface between the FDTI and BDTI structures.

FIG. 13 shows various views of a four-cell pixel unit.

FIG. 14A shows additional various views of a four-cell pixel unit.

FIG. 14B shows additional various views of a four-cell pixel unit.

Corresponding reference characters indicate corresponding components throughout the several views of the drawings. Skilled artisans will appreciate that elements in the figures are illustrated for simplicity and clarity and have not necessarily been drawn to scale. For example, the dimensions of some of the elements in the figures may be exaggerated relative to other elements to help to improve understanding of various embodiments of the present invention. Also, common but well-understood elements that are useful or necessary in a commercially feasible embodiment are often not depicted in order to facilitate a less obstructed view of these various embodiments of the present invention.

### DETAILED DESCRIPTION

Examples in accordance with the teaching of the present invention describe a pixel cell with a frontside deep trench isolation (FDTI) structure and a backside deep trench isolation (BDTI) structure. In the following description, numerous specific details are set forth to provide a thorough understanding of the examples. One skilled in the relevant art will recognize, however, that the techniques described herein can be practiced without one or more of the specific details, or with other methods, components, materials, etc. In other instances, well-known structures, materials, or operations are not shown or described in detail in order to avoid obscuring certain aspects.

In the following description, numerous specific details are set forth to provide a thorough understanding of the examples. One skilled in the relevant art will recognize, however, that the techniques described herein can be practiced without one or more of the specific details, or with other methods, components, materials, etc. In other instances, well-known structures, materials, or operations are not shown or described in detail in order to avoid obscuring certain aspects.

Spatially relative terms, such as “beneath,” “below,” “over,” “under,” “above,” “upper,” “top,” “bottom,” “left,” “right,” “center,” “middle,” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is rotated or turned over, elements described as “below” or “beneath” or “under” other elements or features would then be oriented “above” the other elements or features. Thus, the exemplary terms “below” and “under” can encompass both an orientation of above and below. The device may be otherwise oriented (rotated ninety degrees or at other orientations) and the spatially relative descriptors used herein interpreted accordingly. In addition, it will also be understood that when an element is referred to as being “between” two other elements, it can be the only element between the two other elements, or one or more intervening elements may also be present.

Throughout this specification, several terms of art are used. These terms are to take on their ordinary meaning in the art from which they come, unless specifically defined herein or the context of their use would clearly suggest otherwise. It should be noted that element names and symbols may be used interchangeably through this document (e.g., Si vs. silicon); however, both have identical meaning.

As will be discussed, various examples of FDTI structures and BDTI structures are disclosed. The FDTI structure is disposed on a frontside of a semiconductor substrate or semiconductor material. The FDTI structure comprises a first trench, a first electrically isolating material and a first conductive material. The first trench is formed from a frontside surface of the semiconductor substrate, and the first trench extends a first depth into the semiconductor substrate from the frontside surface of the semiconductor substrate. The first electrically isolating material lines first sidewalls and a first bottom surface of the first trench and the first conductive material is disposed in the first trench on the first electrically isolating material. The BDTI structure is disposed on a backside surface of the semiconductor substrate, wherein the backside surface is opposite to the frontside surface. The BDTI structure comprises a second trench, a second electrically isolating material and a second conductive material. The second trench is formed from the backside surface of the semiconductor substrate, and the second trench extends a second depth into the semiconductor substrate from the backside surface of the semiconductor substrate, wherein the backside surface is opposite to the frontside surface. The second electrically isolating material lines second sidewalls and a second bottom surface of the second trench and the second conductive material is disposed in the second trench on the second electrically isolating material. In one example, the first trench of the FDTI structure and the second trench of the BDTI structure are electrically isolated from one another. This allows for the first conductive material of the FDTI structure and the second conductive material of the BDTI stricture to each be individually biased by voltage sources with different voltages. As will be shown, in various examples, the disclosed pixel cells utilizing FDTI, and BDTI structures with appropriate biasing operations can provide high full well capacity (FWC) and higher near infrared (NIR) quantum efficiency.

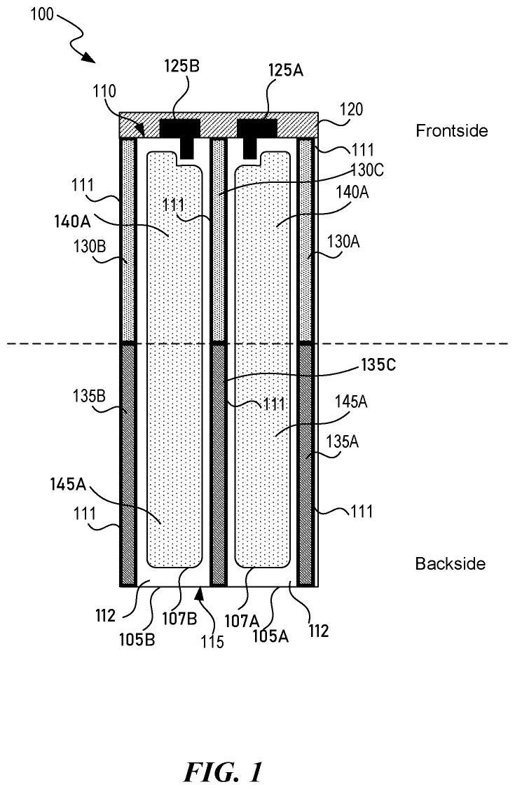

FIG. 1 depicts an example cross-section view of two adjacent pixel cells 105A and 105B that may be included in an example four-cell pixel unit with a frontside surface 110 and a backside surface 115 in accordance with an embodiment of the present disclosure. The frontside surface 110 is opposite to the backside surface 115. Pixel cell 105A (105B) includes a semiconductor substrate 112 (also referred to herein as a semiconductor material). The semiconductor substrate 112 may be comprised of a silicon substrate, a silicon germanium alloy, germanium, a silicon carbide alloy, an indium gallium arsenide alloy, any other alloys formed of III-V compounds, or a bulk substrate, photodiodes 107A, 107B, FDTI structures 130A, 130B, 130C and BDTI structures 135A, 135B, 135C, and transfer transistors 125A, 125B. The photodiodes 107A, 107B may be disposed in an epitaxial layer in the semiconductor substrate 112. Each of the FDTI structures 130A, 130B, and 130C may include a first trench having first sidewalls and a first bottom surface lined with a first electrically isolating or insulating material (e.g., silicon oxide) and filled with a first conductive material. The first conductive material is separated from the semiconductor substrate 112 by the first electrically isolating material. Each of the BDTI structures 135A, 135B, and 135C may also include a second trench having second sidewalls and second bottom surface lined with a second electrically isolating material (e.g., silicon oxide) and filled with a second conductive material. The second conductive material is separated from the semiconductor material 112 by the second electrically isolating material. In the illustrated embodiments, pixel cells 105A and 105B share FDTI structure 130C which lies between pixel cells 105A and 105B. Pixel cells 105A and 105B also share BDTI structure 135C which lies between the pixel cells 105A and 105B. FDTI structures 130A, 130C and BDTI structures 135A, and 135C may collectively define pixel region for pixel cell 105A. FDTI structures 130B, 130C, and BDTI structures 135B, 135C may collectively define pixel region for pixel cell 105B. Surrounding a portion (e.g., transfer gate) of the transfer transistor 125A (125B) is inter-layer dielectric 120. That is, the transfer gate of the transfer transistor 125A (125B) is embedded within layer dielectric 120. The first conductive material disposed on the first electrically isolating material in the respective first trenches of the FDTI structures 130A, 130B, 130C can be coupled to receive a first bias voltage, and the second conductive material disposed on the second electrically isolating material in respective second trenches of the BDTI structures 135A, 135B, 135C can be coupled to receive a second bias voltage that is the same or different from the first bias voltage. The first bias voltage applied to the first conductive material of FDTI structures 130A, 130B, 130C may generate electric fields affecting electric potential of the corresponding photodiode region of respective photodiode 107A, 107B. The second bias voltage applied to the second conductive material of BDTI structures 135A, 135B, 135C may generate electric fields affecting electric potential of the corresponding photodiode region of respective photodiode 107A, 107B. For example, the first bias voltage applied to the first conductive material of FDTI structures 130A, 130B, 130C tends to affect the movement of charges in the region of the respective photodiode 107A, 107B towards or near the frontside surface 110 such as the charges within photodiode region 140A of corresponding photodiodes 107A, 107B. Similarly, the second bias voltage applied to the BDTI conductive material tends to affect the movement of charges in the region of the respective photodiode 107A, 107B towards or near the backside surface 115 such as the photodiode region 145A of the photodiode 107A, 107B. The photodiode region 140A (upper portion or first photodiode region) of each of the photodiodes 107A, 107B near frontside surface 110 tends to exhibit surface lag and the photodiode region 145A (lower portion or second photodiode region) of the photodiodes near backside surface 115 tends to exhibit deep pocket lag. Both surface lag and deep pocket lag may slow the transfer of charge out of the photodiodes and result in image lag affecting signal readout, especially for capturing scenes with low light intensity. In some embodiments the first and second bias voltages are adjusted to reduce the surface and deep pocket lag times.

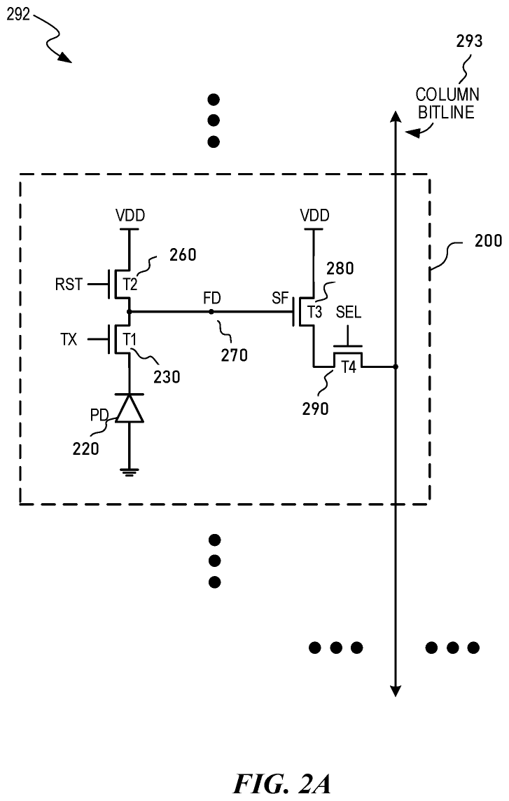

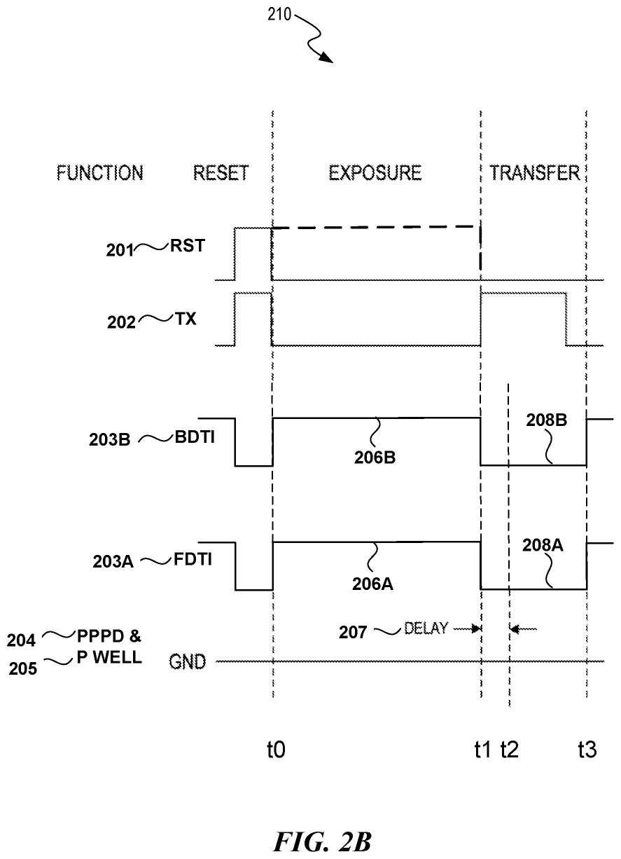

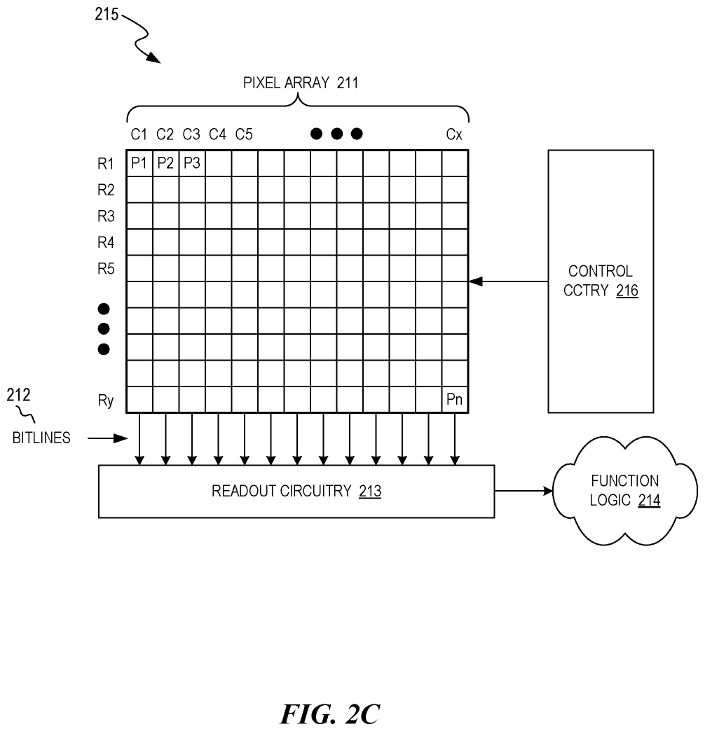

To illustrate the use of a pixel cell such as pixel cell 105A or 105B, FIG. 2A shows a schematic illustrating one example of pixel cell 200 that may be one of a plurality of pixel cells that are arranged in an example pixel array 292 having FDTI and BDTI structures and other structures in accordance with the teachings of the present invention. In the depicted example, pixel cell 200 is illustrated as being a four-transistor (“4T”) pixel cell included in a backside illuminated image sensor in accordance with the teachings of the invention. It is appreciated that pixel cell 200 is one possible example of pixel circuitry architecture for implementing each pixel cell within pixel array 292 of FIG. 2A. However, it should be appreciated that other examples in accordance with the teachings of the present invention are not necessarily limited to 4T pixel architectures. One having ordinary skill in the art having the benefit of the present disclosure will understand that the present teachings are also applicable to 3T designs, 5T designs, and various other pixel architectures in accordance with the teachings of the present invention.

In the example depicted in FIG. 2A, pixel cell 200 includes a photodiode (“PD”) 220 to accumulate image charge, a transfer transistor T1 230, a reset transistor T2 260, a floating diffusion (“FD”) 270, a source-follower (“SF”) transistor T3 280, and a select transistor T4 290. During operation, transfer transistor T1 230 receives a transfer signal TX at transfer gate thereof causing a transfer of the image charge accumulated in photodiode PD 220 to floating diffusion FD 270. In some example embodiments, the floating diffusion FD 270 may be coupled to a storage capacitor for temporarily storing image charges. In some example embodiments and further detailed below, a BDTI structure and an FDTI structure are included in pixel cell 200 that, in response to the transfer signal TX, are selectively coupled the first and second bias voltages to reduce charge transfer lag. The first and second bias voltages may be adjusted between the integration and charge transfer periods of pixel cell 200. The charge period occurs after the integration period. In the charge transfer period, the transfer transistor T1 230 selectively transfers the image charge from the photodiode PD 220 to the floating diffusion FD 270 in accordance with the teachings of the present invention.

As shown in the illustrated example of FIG. 2A, reset transistor T2 260 is coupled between a power rail VDD and the floating diffusion FD 270 to reset the pixel cell 200 (e.g., discharge or charge the floating diffusion FD 270 and the photodiode PD 220 to a preset voltage) in response to a reset signal RST received at its gate. The floating diffusion FD 270 is coupled to control the gate of SF transistor T3. SF transistor T3 is coupled between the power rail VDD and select transistor T4. SF transistor T3 operates as a source-follower amplifier providing a high impedance connection to the floating diffusion FD 270. Select transistor T4 290 selectively couples the output of pixel cell 200 to the readout column bitline 293 in response to a select signal SEL received at its gate.

In some example embodiments, the transfer signal TX, the reset signal RST, the select signal SEL, and the first and second bias voltages applied to the first and second conductive materials of FDTI and/or BDTI structures, are generated by control circuitry, an example of which will be described in further detail below. In an example in which pixel array 292 operates with a global shutter, the global shutter signal is coupled to the gate of each transfer transistor T1 230 in the pixel array 292 to simultaneously commence charge transfer from each pixel's photodiode PD 220. Alternatively, rolling shutter signals may be applied to groups of transfer transistors T1 230 in accordance with the teachings of the present invention.

FIG. 2B illustrates a timing diagram 210 of example signals in example pixel cell 200 of FIG. 2A and/or in example pixel cell 105A (105B) of FIG. 1, which have deep trench isolation structures, e.g., FDTI and BDTI structures, in accordance with the teachings of the present invention. As illustrated in the depicted example, timing diagram 210 shows that prior to time t0, a reset function occurs in which the reset signal RST 201 is applied to for example the gate terminal of reset transistor T2 260 of FIG. 2A, and that the transfer signal TX 202 is applied to, for example, the gate terminal of transfer transistor T1 230 of FIG. 2A. The first conductive material of respective FDTI structure 130A, 130B, 130C of FIG. 1 is coupled to receive a first bias voltage 203A. The second conductive material of respective BDTI structure 135A, 135B, 135C of FIG. 1 is coupled to receive a second bias voltage 203B. During this reset period prior to time to in FIG. 2B, the voltage at floating diffusion FD 270 and photodiode PD 220 of FIG. 2A, and/or the photodiode 107A (107B) of FIG. 1, are reset to the power rail VDD voltage, which discharges or charges the floating diffusion FD 270 and the photodiode PD 220 and/or the photodiode 107A (107B) of FIG. 1 to a preset voltage. During the reset period prior to time to in FIG. 2B, the first bias voltage 203A applied to respective BDTI structure 135A, 135B, 135C of FIG. 1 and the second bias voltage 203B can each be set to a negative bias voltage level to mitigate lag issue during photodiode reset operation such as deep pocket lag.

FIG. 2B illustrates that after the reset function is completed at time to, the photodiode is illuminated (or continues to be illuminated) with light during an exposure or integration period between time t0 and t1 to accumulate image charge in the photodiode, which is illustrated for example in FIG. 1 with light being directed to photodiode 105A (105B) through backside 115 of semiconductor substrate 112 (also referred to herein as a semiconductor material). It is appreciated that during the exposure or integration period between time t0 and t1, the reset transistor 260 may be turned on via reset signal RST to drain out excess charges from floating diffusion FD 270 during the exposure or integration period, thus providing anti-blooming functionality to improve blooming performance of an image sensor having a pixel array including pixel cell 200.

In FIG. 2B during the integration period between time t0 and t1, the first conductive material of respective FDTI structure 130A, 130B, 130C is coupled to receive the first bias voltage 203A having a first negative bias voltage level at 206A. During the integration period between time t0 and t1, the second conductive material of respective BDTI structure 135A, 135B, 135C is coupled to receive a second bias voltage 203B having a second negative bias voltage level at 206B. The first and second bias voltages 203A, 203B can cause the FDTI structure 130A, 130B, 130C, and BDTI structures 135A, 135B, 135C to each generates a corresponding electric field forming hole accumulation regions around each of FDTI structures 130A, 130B, 130C, and BDTI structures 135A, 135B, 135C, suppressing defects and/or trap sites formed at interface between the semiconductor substrate and respective electrically isolating material due to processing damage (e.g., plasma etching damage or implantation damage), thereby improving dark current performance. It is appreciated that the first negative bias voltage level of first bias voltage 203A may be different from the second negative bias voltage level of the second bias voltage 203B. It is further appreciated that the negative bias voltage level individually applied to FDTI structures 130A, 130B, 130C, and BDTI structures 135A, 135B, 135C during reset may be respectively different from the first negative bias voltage level of first bias voltage 203A and the second negative bias voltage level of the second bias voltage 203B.

FIG. 2B shows that after the integration period is completed at time t1, the image charge accumulated in the photodiode (e.g., photodiode PD 220) is then transferred from the photodiode(e.g., photodiode PD 220) through the transfer transistor (e.g., transfer transistor 230) to the floating diffusion during the transfer function between time t1 and t3. FIG. 2B shows that this process begins with the transfer signal TX 202 being applied to turn on the transfer transistor, such as for example transfer transistor 230 of FIG. 2A, or transfer transistor 125A (125B) of FIG. 1. In one example, after a time delay from t1 to t2, the first conductive materials of the FDTI structures 130, 130B, 130C and the second conductive material of BDTI structures 135A, 135B, 135C of FIG. 1, are coupled to receive first and second bias voltages, respectively. The first and second bias voltages may be modulated during the operation of a pixel cell. For example, during the integration period between t0 and t1 in FIG. 2B, the photodiode accumulates photo-generated charges while the transfer signal TX 202 turns-off the transfer transistor. During the transfer period between t1 and t3 in FIG. 2B, the transfer signal TX 202 turns-on the transfer transistor to transfer the image charge from the photodiode to the floating diffusion. (Note that FIG. 2B shows transfer signal TX 202 turning off transfer transistor before time t3.) In some embodiments, the time delay between time t1 and t2 is greater than or equal to zero. In some example embodiments the first bias voltage 203A having the first negative voltage level and the second bias voltage 203B having the second negative voltage level may be respectively applied to the first conductive material of the FDTI structures 130A, 130B, 130C and the second conductive material of the BDTI structures 135A/B/C between time t2 and t3 during the readout operation of the image charge from the photodiode 220 (FIG. 2A) as illustrated by 208A, 208B. In some embodiments, the negative voltage levels of first and second bias voltage 203A, 203B applied during readout period may be different from the first and second negative voltage levels applied during integration period. The applied first and second bias voltages reduce image lag in accordance with the teachings of the present invention as the electric fields created by the first and second bias voltages 203A, 203B helps to facilitate transferring the image charge accumulated in the photodiode 220 to the floating diffusion FD 270 through the transfer transistor 230 in accordance with the teachings of the present invention. In the example of FIG. 2B, after the transfer operation is completed at time t3, the FDTI structures 130A, 130B, 130C and BDTI structures 135A, 135B, 135C are respectively biased with first and second bias voltages each with bias voltage level that is greater than first and second negative bias levels or at zero voltage. Thereafter a negative bias voltage (e.g., such as negative bias level at 206A, 206B) can be once again respectively applied to the FDTI structures 130A, 130B, 130C and BDTI structures 135A, 135B, 135C.

FIG. 2C shows a diagram illustrating an example of an imaging system 215 including a pixel array 211 having pixel cells with deep trench isolation structures in accordance with the teachings of the present invention. As shown in the depicted example, imaging system 215 includes pixel array 211 coupled to control circuitry 216 and readout circuitry 213, which is coupled to function logic 214.

In some example embodiments, pixel array 211 is a two-dimensional (2D) array of imaging sensors or pixel cells (e.g., pixel cells P1, P2 . . . , Pn). In some example embodiments, each pixel cell is a CMOS imaging pixel. It is noted that the pixel cells P1, P2, . . . . Pn in the pixel array 211 may be examples of pixel cell 200 of FIG. 2A and/or of pixel cell 100 of FIG. 1 and that similarly named and numbered elements referenced below are coupled and function similar to as described above. In some embodiments, deep trench isolation structures may be arranged in between pixel cells. The deep trench isolation structures may be arranged in a grid thereby defining an area or region associated with each pixel cell and separating adjacent pixel cells. Deep trench isolation structures may include FDTI structures (such as FDTI structures 130A, 130B, 130C of FIG. 1) and/or BDTI structures (such as BDTI structures 135A, 135B, 135C of FIG. 1). As illustrated in FIG. 2C, each pixel cell can be arranged in a row (e.g., rows R1 to Ry) and a column (e.g., column C1 to Cx) to acquire image data of a person, place, object, etc., which can then be used to render a 2D image of the person, place, object, etc.

In some example embodiments, after each pixel cell has accumulated its image data or image charge, the image data is readout by readout circuitry 213 through readout column bitlines 212 and then transferred to function logic 214. In various examples, readout circuitry 213 may include amplification circuitry, analog-to-digital (ADC) conversion circuitry, or otherwise. Function logic 214 may simply store the image data or even manipulate the image data by applying post image effects (e.g., crop, rotate, remove red eye, adjust brightness, adjust contrast, or otherwise). In some example embodiments, readout circuitry 213 may readout a row of image data at a time along readout column bitlines 212 (illustrated) or may readout the image data using a variety of other techniques (not illustrated), such as a serial readout or a full parallel readout of all pixels simultaneously.

Control circuitry 216 may be coupled to pixel array 211 to control operational characteristics of the pixel cells of the pixel array 211. For example, control circuitry 216 can be configured to control the voltage amplitudes and the timing of the first and second bias voltages applied to the respective conductive materials of the FDTI and BDTI structures. Control circuitry 216 may generate a shutter signal for controlling image acquisition. In one example, the shutter signal is a global shutter signal for simultaneously enabling all pixels within pixel array 211 to simultaneously capture their respective image data during a single acquisition window. In another example, the shutter signal is a rolling shutter signal such that each row, column, or group of pixels is sequentially enabled during consecutive acquisition windows.

In some embodiments, imaging system 215 can be implemented on a single semiconductor wafer. In some other embodiments, imaging system 215 can be implemented on stacked semiconductor wafers. For example, pixel array 211 can be implemented on a pixel wafer or a sensor wafer, and readout circuit 213, control circuit 216 and function logic 214 can be implemented on an application specific integrated circuit (ASIC) wafer, where the pixel wafer and the ASIC wafer are stacked and interconnected by bonding (hybrid bonding, oxide bonding, or the like) or one or more through substrate vias (TSVs). The ASIC wafer may further include biasing voltage source configured to generate the first and second bias voltages. In some embodiments, pixel array 211 and control circuit 216 can be implemented on a pixel wafer, and readout circuit 213, and function logic 214 can be implemented on an ASIC wafer, where the pixel wafer and the ASIC wafer are stacked and interconnected by bonding (hybrid bonding, oxide bonding, or the like) or one or more through substrate vias (TSVs).

In some embodiments, imaging system 215 may be included in a digital camera, cell phone, laptop computer, endoscope, security camera, imaging device for automobile, or the like. Additionally, imaging system 215 may be coupled to other hardware such as a processor (general purpose or otherwise), memory devices, electrical output ports (USB port, wireless transmitter, HDMI port, etc.), lighting/flash, electrical input ports (keyboard, touch display, track pad, mouse, microphone, etc.), and/or display. Other hardware may deliver instructions to imaging system 215, extract image data from imaging system 215, or manipulate image data supplied by imaging system 215.

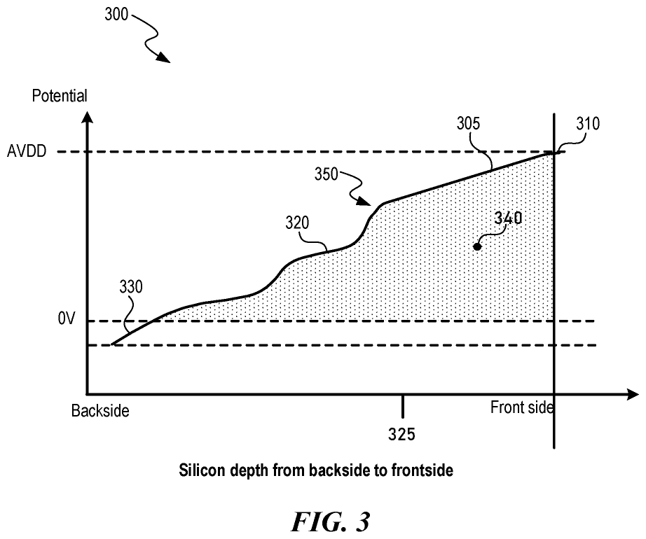

FIG. 3 (in view of FIG. 1) shows an example of a plot of electric potential in volts vs. position in depth in a photodiode region of a photodiode in a pixel cell from the backside surface 115 to the frontside surface 110, in accordance with some example embodiments. In some embodiments with small pixels (e.g., submicron pixels such as pixel size less than or equal to 0.7 um), it is desirable to have a high full well capacity (FWC), and/or a high near infrared (NIR) quantum efficiency (QE). FWC refers to amount of photogenerated charges that can be accumulated and stored in a photodiode, which can be defined by, or determined from, the area 340 “under the electric potential curve” 350.

The disclosed subject matter includes 1) tending to limit the full well capacity of the photodiode are a) the thickness of the semiconductor substrate (e.g., silicon substrate) due to the deep trench isolation (DTI) production process including an aspect ratio and b) a requirement for a positive slope of the potential curve vs. depth from backside surface 115 to frontside surface 110 to reduce charge transfer lag; and 2) higher NIR quantum efficiency tends to require a thicker semiconductor substrate, but the substrate thickness may be limited by parameters of the DTI production process (e.g., etching depth, trench aspect ratio, and material deposition capability), thereby limiting NIR QE. The disclosed techniques reduce or eliminate charge transfer lag using, for example, the first bias voltage applied to the first conductive materials of the FDTI structures 130A, 130B, 130C in FIG. 1 and the second bias voltage applied to the second conductive materials of the BDTI structures 135A, 135B, 135C in FIG. 1. This allows for an image sensor having thicker substrate thickness (e.g., 3-7 um), thereby increasing FWC and NIR QE associated with respective pixel cells.

The y-axis of FIG. 3 corresponds to electric potential in Volts and the x-axis corresponds to a depth or distance (e.g., in microns) from the backside surface 115 of the semiconductor material or the semiconductor substrate 112 (closer to the photodiode region 145A of FIG. 1) to the frontside surface 110 of the semiconductor substrate 112 (closer to the planar gate portion of the transfer gate on the semiconductor substrate 112). In some embodiments, the backside surface 115 of the semiconductor substrate 112 may be an illuminated side surface of an image sensor, and the frontside surface 110 of the semiconductor substrate 112 may be a non-illuminated side of the image sensor. Shown along the x-axis are example locations for the BDTI structure, which has a second bias voltage applied to a corresponding second conductive material thereof, and the FDTI structure, which has a first bias voltage applied to a corresponding first conductive material thereof. On the plot 350 in FIG. 3, the photodiode region near the backside surface 115 of the semiconductor substrate 112 such as at depth 330, the electric potential of a corresponding section in the photodiode region 145A, 145B in FIG. 1 can be adjusted by the second bias voltage applied to the second conductive materials of the BDTI structures 135A, 135B, 135C, and the region of the photodiode near the frontside surface 110 such as at depth 305, the electric potential of the corresponding section in the photodiode region 140A, 140B can be adjusted by the second bias voltage applied to the FDTI structures 130A, 130B, 130C.

In the example of FIG. 3, the first and second bias voltages can be configured to modulate or adjust the slope of curve 350 such that curve 350 is a curve with positive slope from the photodiode region near the backside surface 115 of the semiconductor substrate 112 to the photodiode region near the frontside surface 110 of the semiconductor substrate 112. The positive slope reduces deep pocket lag, which may occur in part of the photodiode region near the backside of the semiconductor substrate 112, such as in region at 320. As described below, surface lag occurs near the frontside of the semiconductor substrate 112. Moving from the backside surface 115 to the frontside surface 110 in distance, depth 325 on the x-axis of FIG. 3 shows an example transition location from the BDTI structure to the FDTI structure. Depth 325 is shown as an illustrative example depth, which can change according to a particular implementation as well as extended depth of respective BDTI and FDTI structures in the semiconductor substrate 112. FIG. 3 may provide an exemplary representation of a desirable plot of electric potential vs. depth. By properly configuring the first and second bias voltages, electric potential along depthwise direction in the semiconductor substrate can be modulated to avoid lag issue while maximizing full well capacity of the respective photodiode (e.g., maximizing area under electric potential curve 350). Different photodiode configurations (e.g., doping concentration and doping profile) may require different first and second bias voltages to modulate the associated electric potential curve such as curve 350 to have a positive slope trend from backside to the frontside of the semiconductor substrate.

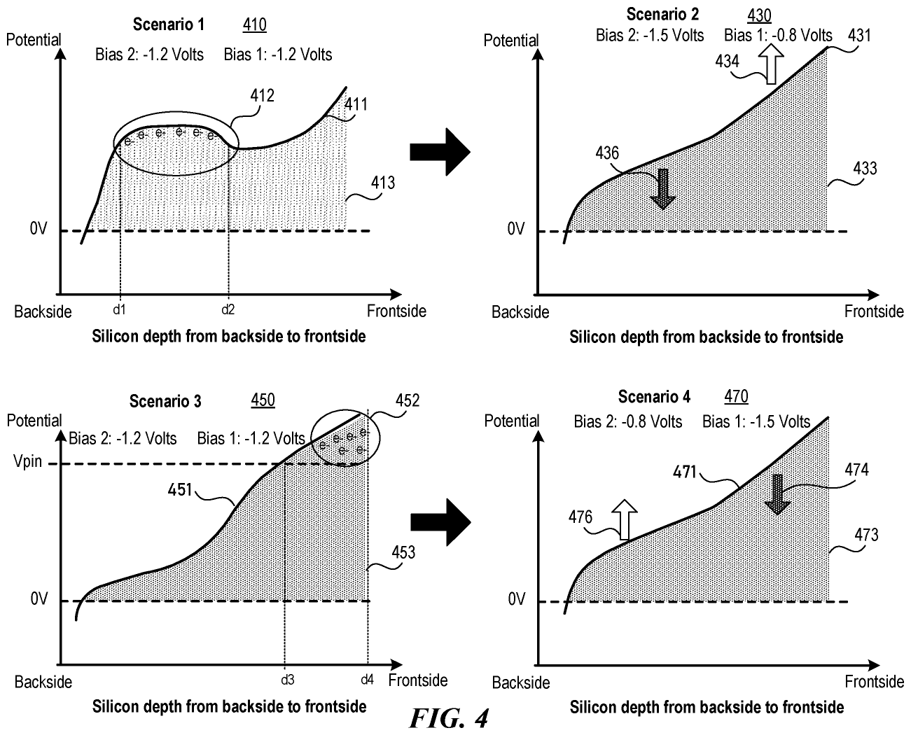

FIG. 4 shows four example plots of electric potential (volts) with respect to location or region of photodiode between the backside to the frontside of the semiconductor substrate. The different scenarios shown in the examples illustrate the benefits being able to individually apply first bias voltage applied to a first conductive material of a FDTI structure and a second bias voltage applied to a second conductive material of a BDTI structure. The first bias voltage and second bias voltage may be applied separately and can be different depends on the operational needs.

Pinning voltage, Vpin, is a property of a photodiode that is generated based on the doping concentration or doping profile associated with the photodiode region of the photodiode and is limited by the pixel voltage AVDD (e.g., an analog voltage for resetting photodiode and floating diffusion such as VDD in FIG. 2A). Pinning voltage Vpin is a voltage where the photodiode is fully depleted or a voltage where the photodiode is empty of free charges. When pinning voltage Vpin is too high, it can impede or hinder charge transfer from the photodiode to the floating diffusion leading to deep pocket lag issue. The first and second bias voltages may be selected based on, at least in part, the pinning voltage Vpin of the photodiode. For example, the first bias voltage may be selected to be a negative voltage applied to the first conductive material of the FDTI structure which creates an electric field that tunes the electric potential of the photodiode region, which minimizes surface lag at the same time as reducing the dark current caused by surface defects. The second bias voltage may be selected to be a negative voltage applied to the second conductive material of the BDTI that tunes the electric potential associated with photodiode region near the backside to be below zero volts which is the electrical potential of the semiconductor substrate shown at 330 to minimize deep pocket lag and improve white pixel performance

Plot 410 in FIG. 4 shows an example scenario 1 in which a first bias voltage Bias1 of −1.2V is applied to the FDTI structure and a second bias voltage Bias2 of −1.2V is applied to the BDTI structure may cause the photodiode in proximity to have the electric potential curve 411. The photodiode in this example with the foregoing bias voltages applied may exhibit deep pocket lag in region 412 where charges are trapped thereby creating a lag time during charge transfer because the trapped charges have farther to travel to be transferred out of the photodiode. The charges are trapped between depths d1 and d2 shown at plot 410. The deep pocket lag can be eliminated by changing the first and second bias voltages Bias1, Bias2 in scenario 1 to different bias voltages shown in scenario 2 depicted by plot 430. Plot 430 illustrates an electric potential curve 431 of the photodiode as result of changing the first bias voltage Bias1 applied to the first conductive material of FDTI structure to a less negative voltage, and the second bias voltage Bias2 is changed to a more negative voltage. For example, the first bias voltage Bias1 is changed from −1.2V to −0.8V, and the second bias voltage Bias2 is changed from −1.2V to −1.5V. In scenario 2, the electric potential curve 431 has changed from electric potential curve 411 depicted in plot 410 in response to the changed first and second bias voltages Bias1, Bias2 to the first conductive materials of the FDTI structures and the second conductive materials of BDTI structures. In scenario 2, applying the more negative second bias voltage Bias2 decreases the associated electric potential of the photodiode region of the photodiode proximate to the backside thereby pulling down the section of electric potential curve 431 corresponding to depths d1 and d2 as shown at 436, which helps to reduce or eliminate the deep pocket lag. Applying the less negative first bias voltage Bias1 increases the associated electric potential of the photodiode in the substrate region proximate to frontside and pulls the corresponding section of curve 431 upward as shown at 434 increasing the area under the electric potential curve 431, which can increase the full well capacity of the photodiode.

Plot 450 of FIG. 4 at shows scenario 3 in which a first bias voltage of −1.2V is applied to the FDTI structure and a second bias voltage of −1.2V is applied to the BDTI structure producing the electric potential curve 451. The photodiode in scenarios 2 and 4 have a very high pinning voltage, pinning voltage Vpin (e.g., greater than or equal to 2.8V). The photodiode in this example with the foregoing bias voltages applied may exhibit surface lag in region 452 where charges are trapped thereby causing a lag during charge transfer because the trapped charges have farther to travel to be transferred out of the photodiode or may cause an insufficient charge transfer. The charges are trapped in region 452 between depths d3 and d4 shown in plot 450. The surface lag is eliminated by changing the first and second bias voltages Bias1, Bias2 in scenario 3 to different bias voltages shown in scenario 4. Scenario 4 illustrated by plot 470 has the first bias voltage Bias1 changed to a more negative voltage, such as from −1.2V to −1.5V and the second bias voltage Bias2 changed to a less negative voltage such as from −1.2V to −0.8V. In scenario 4, the electric potential curve 471 has changed from electric potential curve 451 in plot 450 in response to the changed first and second bias voltages Bias1, Bias2. In scenario 4, applying the less negative second bias voltage to the second conductive material of the BDTI structure increases the electric potential of the photodiode region of the photodiode near the backside of the semiconductor substrate, thereby pulling up the corresponding section of curve 471 as shown at 476, which can increase the full well capacity of the photodiode. Applying the more negative first bias voltage to the BDTI structure decreases the electric potential of the photodiode near the frontside pulling down the rightmost section of electric potential curve 451 as shown at 474, which helps to mitigate surface lag issue.

In embodiments, each of first and second bias voltages Bias1, Bias 2 can be adjusted based on characteristics of the photodiode being used (e.g., concentration profile associated with the photodiode from frontside surface to backside surface) to improve charge transfer and reduce surface lag. In addition, the full well capacity (FWC) of the photodiode can be increased which can provide a more flexible tuning with a large process window. The first and second bias voltages Bias1, Bias 2 can be selected to provide a desired operational performance (e.g., surface lag, dark current, white pixel level, etc.) of an image sensor. In operation, when the first and second bias voltages are negative, the generated electric field forms a hole-rich region around the FDTI and BDTI structures providing a passivation effect thereby reducing the dark current. To reduce image lag and increase the FWC of the photodiode, the first bias voltage Bias1 applied to the first conductive material of the FDTI structure can tune the electric potential associated with the frontside portion of the photodiode and the second bias voltage Bias2 applied to the second conductive material of the BDTI structure can tune the electric potential associated with the backside portion of the photodiode. For example, for a given Vpin, the first and second bias voltages applied to the first conductive materials of the FDTI structures and the second conductive materials of BDTI structures, respectively, can be selected to tune the slope of electric potential of photodiode to ramp upward to increase area under the potential curve to maximize the FWC of the photodiode. In some embodiments, the optimal combination of first and second bias voltages can be obtained during image sensor testing. For example, sweeping the bias voltages can be performed to evaluate the electric potential curve of a given photodiode to determine the best combination of first and second bias voltages for charge integration and charge transfer to achieve desired performance characteristics (e.g., maximize full well capacity at tolerable white pixel level, etc.), and record the voltages in a memory (e.g., a register) of the control circuitry such as control circuitry 216 of FIG. 2C.

When the first and second bias voltages Bias1, Bias 2 are selected to cause the area under the electric potential curve 431 (e.g., area 433) to be larger than the area under the electric potential curve 411 (e.g., area 413) , and when the first and second bias voltages are selected to cause the electric potential curve to trend upward (positive slope everywhere), the first and second bias voltages Bias1, Bias2 combination in scenario 2 (e.g., second bias voltage Bias2 of−1.5V, first bias voltage Bias1 of−0.8V) can be used for both integration and transfer periods of the image sensor.

When the area under the electric potential curve 411 in scenario 1 (e.g., area 413) is larger than the area under the electric potential curve 431 in scenario 2 (e.g., area 433), the bias voltage combination in scenario 1 (e.g., second bias voltage Bias2 of −1.2V, first bias voltage Bias1 of −1.2V) can be applied during the integration period maximizing full well capacity associated with the photodiode and then transition to the bias voltage combination in scenario 2 (e.g., second bias voltage Bias2 of −1.5V, first bias voltage Bias1 of −0.8V) during transfer period to reduce the deep pocket lag.

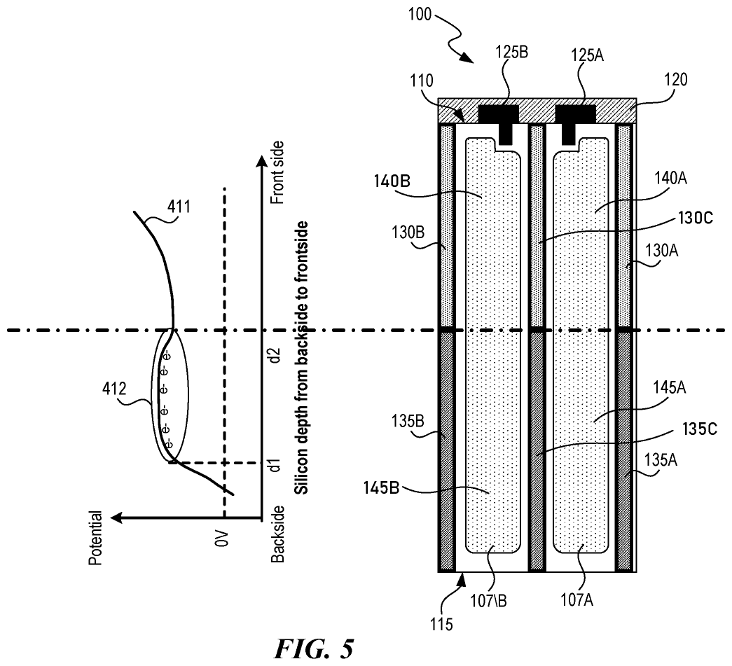

FIG. 5 illustrates example cross-sections of two photodiodes and a plot of electric potential vs. depth in the semiconductor substrate with the depths of the illustrated photodiode aligned with the plot. The photodiodes shown are the same as those in FIG. 1. As can be seen in FIG. 5, the electric potential associated with the region between depth d1 and d2 may induce deep pocket lag by trapping charge carriers as shown at region 412 and can be modulated by applying the appropriate second bias voltage to the conductive material of BDTI structure. Biasing the conductive materials of the FDTI structures such as FDTI structures 130A, 130B, 130C shown in FIG. 1 can tune the electric potential associated with the corresponding photodiode regions 140A/B of the photodiodes 107A, 107B proximate to the surface (frontside) (e.g., applying a less negative bias to generate the electric potential curve with a more positive slope and pull the electric potential curve portion of the electric potential curve near frontside upward). Biasing the conductive materials of the BDTI structures such as BDTI structures 135A, 135B, 135C can tune the electric potential associated with the corresponding photodiode regions 145A, 145B, 145C (deep region proximate to backside) of photodiodes 107A, 107B (e.g., applying a more negative bias voltage to generate a more negative potential and pull the corresponding section (e.g., between depth d1 and d2) of the electric potential curve downward) to reduce the deep pocket lag.

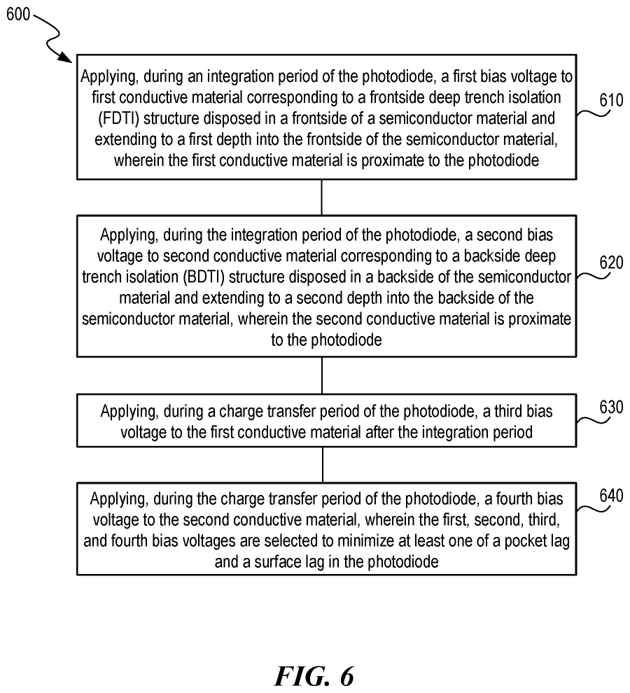

FIG. 6 shows an example method 600 of adjusting the electric potential applied to the conductive materials of the BDTI and FDTI structures that are disposed surrounding a photodiode region of a photodiode, in accordance with some example embodiments. At 610, the method includes applying, during an integration period of the photodiode, a first bias voltage to first conductive material of a frontside deep trench isolation (FDTI) structure disposed on a frontside of a semiconductor material, wherein the FDTI structure extends to a first depth into the semiconductor material with respect to the frontside of the semiconductor material, wherein the first conductive material is proximate to the photodiode. At 620, the method includes applying, during the integration period of the photodiode, a second bias voltage to second conductive material of a backside deep trench isolation (BDTI) structure disposed on a backside of the semiconductor material, wherein the backiside and the frontside of the semiconductor substrate are of opposite sides. The BDTI structure extends to a second depth into the backside of the semiconductor material, wherein the second conductive material is proximate to the photodiode.

During the integration period, the first and the second bias voltages may be applied simultaneously to the first and second conductive materials of the FDTI and BDTI structures, respectively. The first and second bias voltages can be selected based on at least a target full well capacity (FWC) and a dark current count associated with the photodiode. The first and second bias voltages can be selected to be different. The two photodiodes, such as photodiodes 107A, 107B shown in FIG. 1, are coupled to a common floating diffusion.

At 630, the method includes applying, during a charge transfer period of the photodiode, a third bias voltage to the first conductive material, wherein the charge transfer period occurs after the integration period. At 640, the method includes applying, during the charge transfer period of the photodiode, a fourth bias voltage to the second conductive material, wherein the first, second, third, and fourth bias voltages are selected to minimize at least one of a pocket lag and a surface lag in the photodiode. During the charge transfer period, the third and the fourth bias voltages are applied simultaneously to the FDTI and BDTI structures, respectively. The third and fourth bias voltages may be configured to be different depending on charge transfer performance. In some embodiments, the first and third bias voltages have the same value and the second and fourth bias voltages have the same value. In some embodiments, the first, second, third and fourth bias voltages are configured based on an electric potential associated with Vpin voltage or depletion voltage of the photodiodes in FIG. 1 (e.g., average Vpin or the highest Vpin voltage of the first and second photodiodes). In some example embodiments, the first, second, third, and fourth bias voltages applied during the integration and transfer periods are selected according to the considerations detailed above.

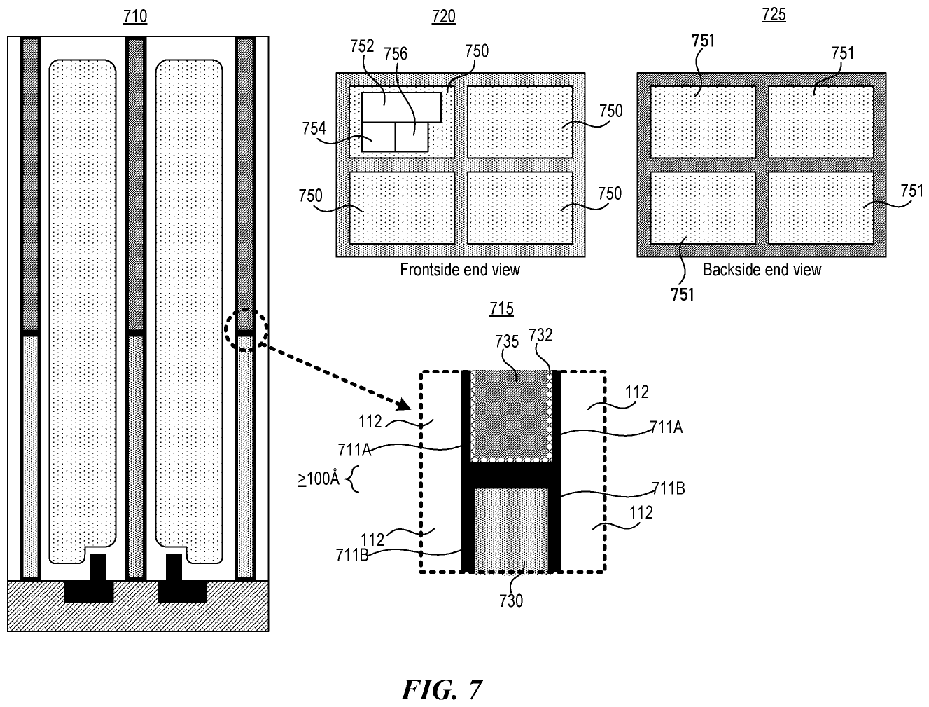

FIG. 7 shows various views of a group of photodiodes. At 710, photodiodes and structures that are the same as, or similar to, FIG. 1 are shown with additional detail. At 715, shown is a detailed view of the junction between the FDTI structure 730 and the BDTI structure 735. In some example embodiments, FDTI structure 730 can include a first conductive material such as conductive polysilicon material, and BDTI structure 735 can include a second conductive material such as a metal material (e.g., aluminum, tungsten, or metal alloys). In other embodiments, the foregoing conductive material layers can be switched or include different conductive materials. It is appreciated, in some embodiments, FDTI structure 730 and BDTI structure 735 can include the same conductive material. Oxide layer 711B surrounds the first conductive material of FDTI structure 730. Oxide layer 711A surrounds the second conductive material of BDTI structure 735 with intervening layer 732. The intervening layer 732 may include one or more material layers to provide anti-reflection and passivation effects. In some embodiments, the intervening layer 732 comprises one or more high k (high dielectric constant) metal oxide material layers, wherein a high k metal oxide material refers to a material containing negative fixed charges and having a dielectric constant greater than 3.9, such as aluminum oxide, hafnium oxide, tantalum oxide, zirconium oxide, and the like. In some embodiments, the oxide layer 711B is adjacent to the oxide layer 711A. In the illustrated embodiments, the FDTI structure 730 and the BDTI structure 735 are at least in a part aligned with each other in a vertical direction. The FDTI structure 730 and BDTI structure 735 may be in contact with each other. For example, the bottom surfaces of FDTI structure 730 and BDTI structure 735 as illustrated at 715 are in contact. In some embodiments, the oxide layer 711B is in contact with the oxide layer 711A. In some embodiments, the oxide layer 711A and 711B separates and isolates the first conductive material of the FDTI structure 730 from the second conductive material of the BDTI structure 735.

FIG. 7 at 720 shows an example view of a pixel layout where each of four photodiodes 750 is isolated or separated from adjacent photodiodes by a frontside deep trench isolation (FDTI) structure. The FDTI structure and the BDTI structure collectively define four regions for the four photodiodes 750 in the illustrated example pixel cell. Regions of each of the four photodiodes 750 may be arranged to include transistor region 752, transfer gate 754 of a transfer transistor, and floating diffusion 756 on frontside 720. Transfer gate 754 may have a vertical electrode extended from the frontside 720 surface into the semiconductor substrate. It is appreciated that the pixel elements arrangement layout illustrated in FIG. 7 is an exemplary layout, and that other arrangements may be possible depending on design criteria. Transfer gate 754 couples the corresponding photodiode 750 to the associated floating diffusion 756. The transistor region 752 may include at least one of a source follower, a reset transistor and a row select transistor. FIG. 7 at 725 shows an example view of a backside 751 and illustrates a backside deep trench isolation (BDTI) structure aligning with the FDTI structure, which separates and isolates the four photodiodes 750.

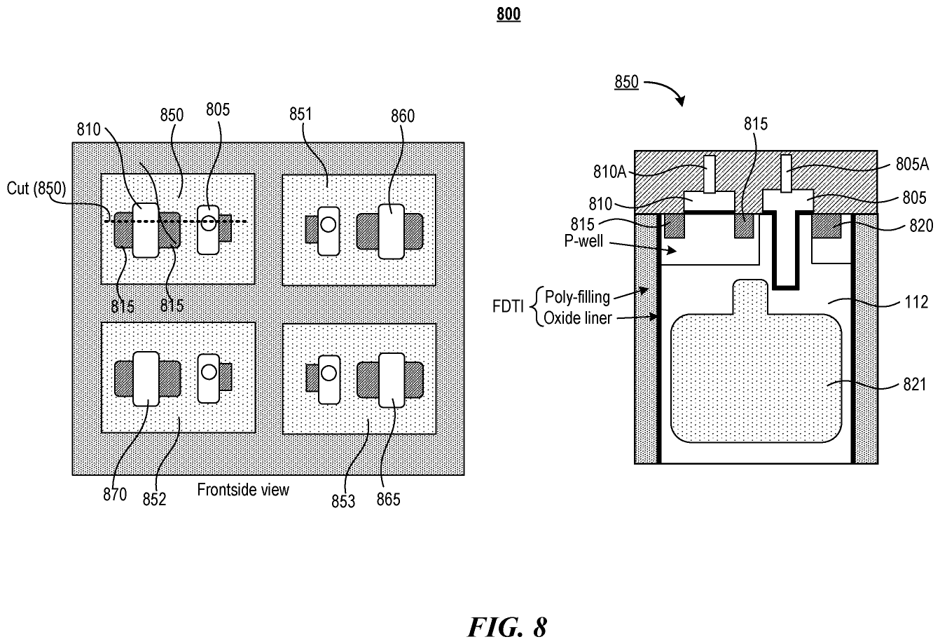

FIG. 8 shows an example diagram 800 of a pixel cell including four subpixels 850, 851, 852, and 853. Each of four subpixels 850, 851, 852, and 853 are separated and isolated by a front side isolation structure. Each sub pixel includes a corresponding photodiode 821, a transfer gate 805, and a floating diffusion 820. The transfer gate 805 couples the respective photodiode 821 to the floating diffusion 820. As illustrated in a horizontal cutline view along sub pixel 850, the transfer gate 805 further includes a vertical gate that extends from the frontside into the semiconductor substrate 112 proximate to the photodiode region (e.g., n-type photodiode doped region) of photodiode 821. The four sub pixels may share at least one pixel transistor such as a source follower 860, a reset transistor 810, a row select transistor 865, or the like. Pixel transistors may be arranged or distributed across four subpixels. In the illustrated embodiment, sub pixel 851 includes source follower 860. Sub pixel 853 includes row select transistor 865. Sub pixel 852 includes dummy transistor 870 which can in other embodiments alternatively be configured as a dual conversion gain (DCG) transistor or as an additional source follower, or a row-select transistor. Sub pixel 850 includes reset transistor 810 that can be controlled by a signal on reset line 810A, and transfer gate 805 controlled by a signal on transfer line 805A. In the illustrated embodiment, the reset transistor 810 includes source/drain areas 815 in a p-well doped into the semiconductor substrate 112 between frontside surface and photodiode 821. In embodiments, one or more of the source follower 860, reset transistor 810, and row select transistor 865 may be formed in an implanted P-well in the semiconductor substrate 112 between frontside surface and a photodiode doped region of the photodiode 821.

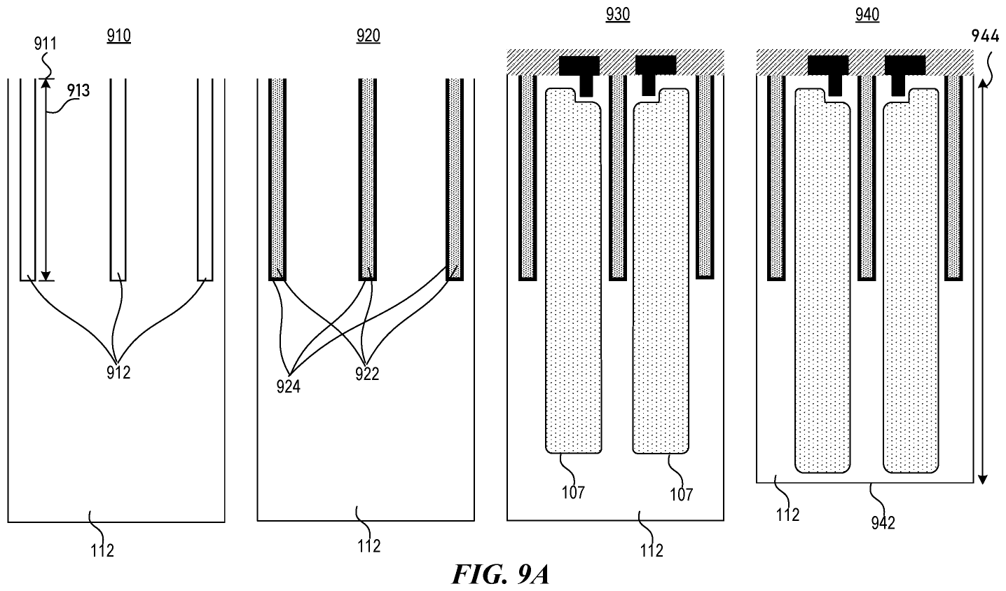

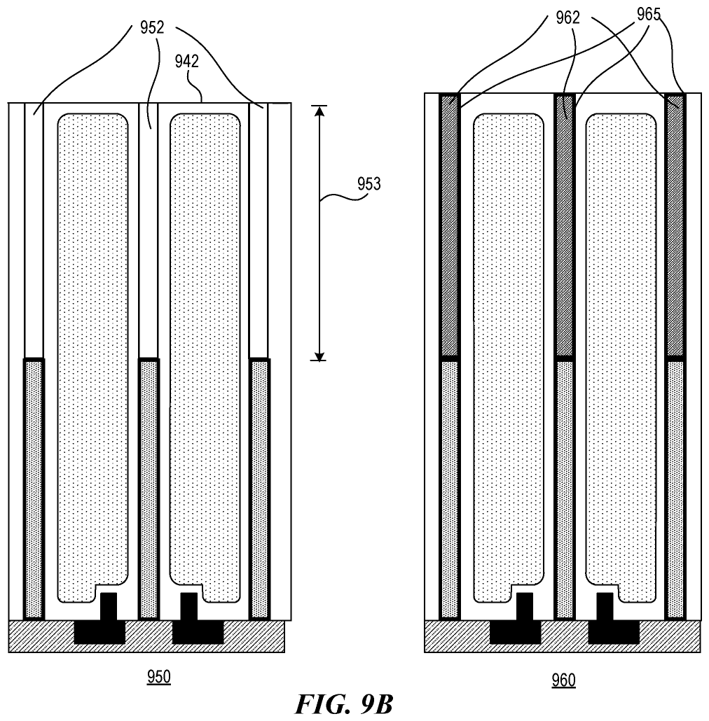

FIG. 9A shows a process for producing FDTI structures, in accordance with some example embodiments. At process 910, a semiconductor substrate 112 is etched to form frontside deep trench isolation (FDTI) structures 912 that extend from the frontside surface 911 to a depth 913 into the semiconductor substrate 112. Depth 913 may be configured based on a substrate thickness of the semiconductor substrate 112. For example, some embodiments have a 3-micron depth 913 while the semiconductor substrate 112 may have 6 to 7-micron substrate thickness. In some embodiments, depth 913 may range between 50-70% of the substrate thickness. The FDTI structures can be formed using photolithography patterning and etching or other semiconductor processing techniques to form trenches for the FDTI structures 912. The trenches formed may be interconnected to form a trench-grid structure. At process 920, liner oxide layer 924 may be deposited on the inside surfaces of trenches of FDTI structures 912. In some embodiments, liner oxide layer 924 may be thermally grown on the inside surfaces of trenches of FDTI structures 912. First conductive material 922 such as metal or polysilicon is further deposited to fill the trenches of the FDTI structures 912 to enable the FDTI structures 912 to be biased generating an electric field to modulate the electric potential of the photodiode region of a photodiode between frontside surface and depth 913. At process 930, other frontside processing is performed to form the frontside structures and devices detailed above in FIGS. 1 and 8 including forming photodiodes 107, floating diffusion, source/drains for transistors, isolation well region via ion implantation, gates for transistors, inter-layer dielectric for embedding gates, metal interconnect (not illustrated), and the like. Photodiodes 107 are implanted in between adjacent FDTI structures 912. In some embodiments, FDTI structures 912 may define photodiode area for photodiodes 107. In some embodiments, photodiodes 107 may be implemented with alignment reference made to FDTI structures 912. Each photodiode 107 has a junction depth that is greater than depth 913 with respect to frontside surface. At process 940, the backside 942 of the semiconductor substrate 112 is thinned to a desired thickness 944. In some example embodiments, the backside 942 is later thinned to a thinner overall thickness such as about 3 to 6 microns.

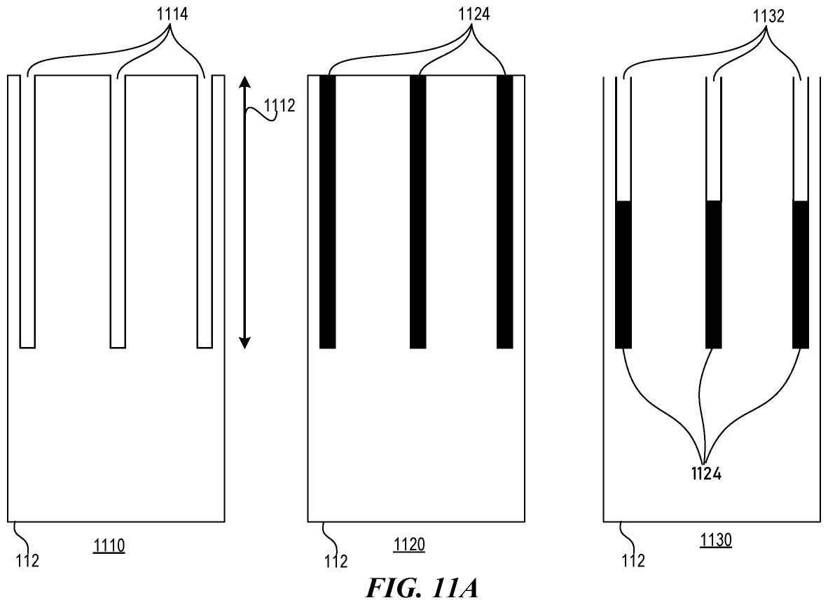

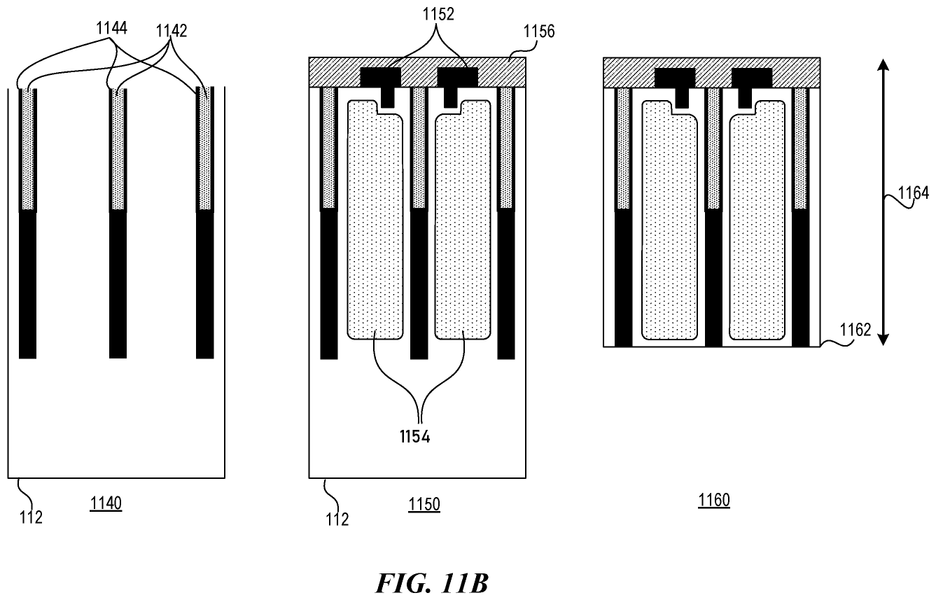

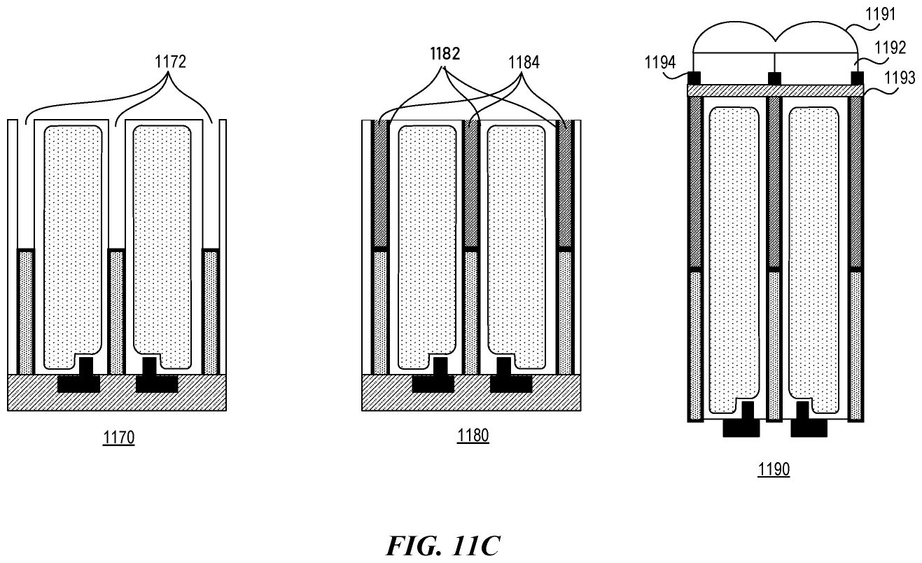

FIG. 9B shows a process for producing BDTI structures, in accordance with some example embodiments. FIG. 9B is a continuation of FIG. 9A. At process 950, after the backside 942 of the semiconductor substrate 112 is thinned to thickness 944 (see FIG. 9A), the backside 942 is patterned and etched to form backside deep trench isolation (BDTI) structures 952 that extend from the backside surface 942 to a depth 953 into the semiconductor substrate. For example, some embodiments have a 2-micron depth 953. The BDTI structures can be formed using photolithography and etching or other semiconductor processing technique to form trenches from the backside 942. The trenches formed for BDTI structures 952 can be interconnected to form a trench-grid structure that is vertically aligned with the FDTI structure 912. In some embodiments, the BDTI structures 952 may be in contact with respective FDTI structures 912. At 960, liner oxide layer 965 may be thermally grown or deposited on the inside surfaces of trenches of BDTI structures 952, and second conductive material 962 such as metal or lightly doped polysilicon is deposited on the liner oxide layer 965 filling each of the trenches to form BDTI structures 952 and enable BDTI structures 952 to be biased generating an electric field to modulate the electric potential of the photodiode between the backside surface 942 and depth 953. As described in FIG. 7, before filling the trenches, one or more material layers having a high dielectric constant (e.g., greater than 3.9 (or high k material layer)) is deposited lining sidewall surfaces of the trenches for BDTI structures 952 and, in some embodiments, on the backside surface 942. The one or more k material layers can be deposited between the liner oxide layer 924 of the FDTI structure 912 and the liner oxide layer 965. Although not shown in FIG. 9B (see, e.g., FIG. 11C), in some example embodiments, on a top outer surface of the BDTI structures 952 and semiconductor substrate at 960, a buffer layer can be added for processing protection, and on top of the buffer layer a metal or composite metal grid is formed to provide optical isolation. Thereafter color (e.g., red, green, blue, IR, etc.) filters can be formed, and microlens can be attached or deposited on top of the color filters to receive incoming light and direct the incoming light to respective photodiode.

With the use of FDTI structures and BDTI structures as described in the foregoing figures, the substrate thickness can be increased because using the disclosed subject matter, full isolation between adjacent pixels can be provided. A thicker silicon substrate can provide for high FWC and high red/near infrared quantum efficiency (QE).

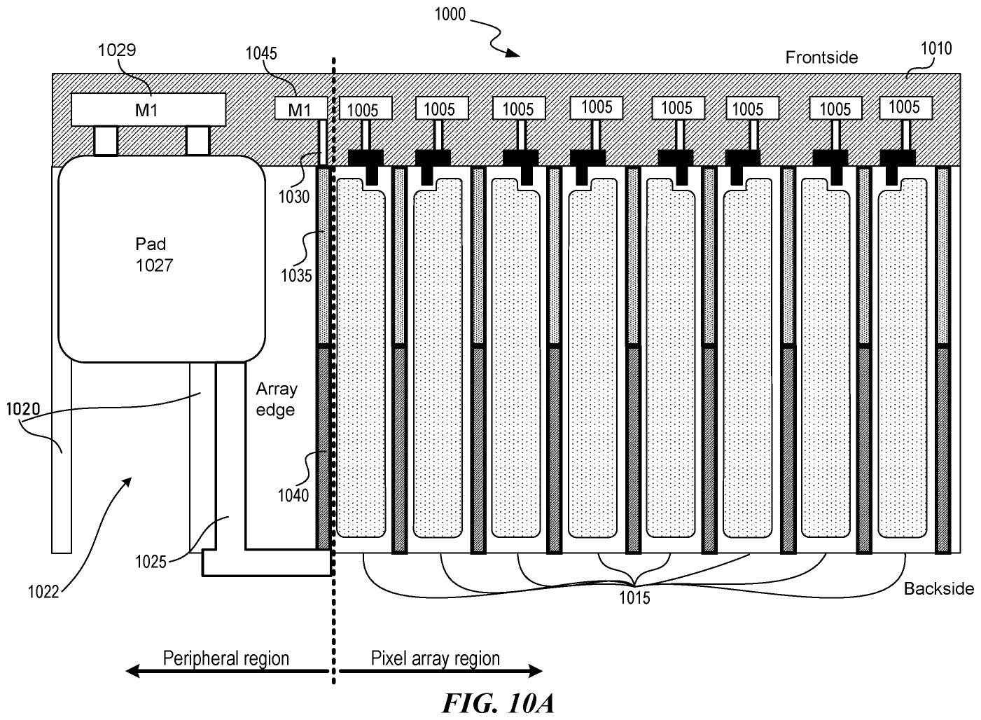

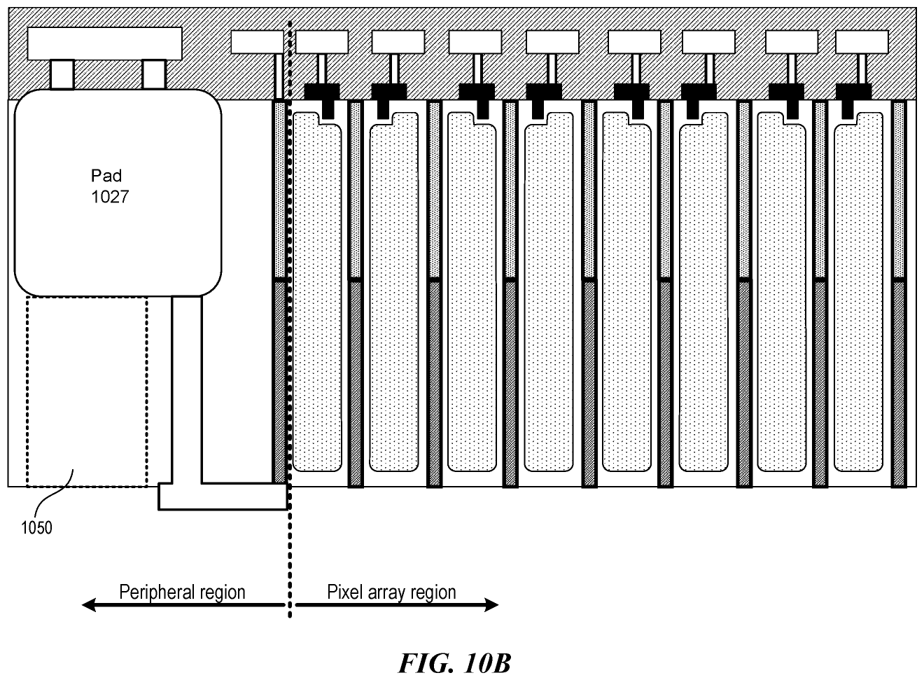

FIG. 10A shows an example 1000 of routing electrical connections to FDTI and BDTI structures in a pixel array. A pixel array region includes a plurality of the photodiodes and supporting structures detailed above. On the edges of the pixel array is a peripheral region. The photodiodes and supporting structures 1015 are the same or similar to those described above. The transfer gate for each photodiode can be connected through a contact via to a respective metal interconnect 1005 in a first metal layer M1. In some example embodiments, some of the metal interconnects 1005 can be electrically connected together enabling charge transfer of multiple photodiodes at the same time such as transfer gates in the same row. Interlayer dielectric 1010 encapsulates the metal interconnect 1005. FDTI structure 1035 connects to a respective metal interconnect 1045 in first metal layer M1 through contact via 1030 to receive a first bias voltage. In some embodiments, FDTI structure 1035 can be connected to a contact pad (not illustrated) of a plurality of contact pads through a respective metal interconnect 1045 in first metal layer M1 and one or more metal interconnects in first metal layer M1 and/or additional metal layers (not illustrated) in peripheral region to receive first bias voltage. FDTI structures 1035 from one or more other photodiode structures 1015 can also be connected to metal interconnect 1045 (not shown). In some embodiments, FDTI structures 1035 may be interconnected forming a FDTI structure grid, thus only one of FDTI structure 1035 needs to be connected to the metal interconnect 1045, such as the FDTI structure 1035 near array edge of the pixel array. BDTI structures 1040 can be connected to a metal interconnect 1029 in the first metal layer M1 through a contact pad 1027 of the plurality of contact pads. The BDTI structures 1040 may be connected to the contact pad 1027 via metal connection 1025 formed on the backside to receive a second bias voltage. The metal connection 1025 may be part of a metal grid (not illustrated) disposed on the backside of the semiconductor material, wherein the metal grid providing optical isolation between adjacent photodiodes included in the pixel array. Contact pad 1027 may be one of multiple contact pads disposed in the peripheral region, wherein the peripheral region surrounds pixel array region. BDTI structures 1040 from one or more other photodiode structures 1015 can also be connected to metal interconnect 1029. In some embodiments, the BDTI structures 1040 may be interconnected forming a BDTI structure grid, thus only one of BDTI structures needs to be connected to the metal interconnect contact pad 1027, such as the FDTI structures near the array edge of the pixel array. Insulation material 1020 such as an oxide-based material (e.g., silicon oxide) may surround contact pad 1027 to provide isolation between the contact pad 1027 and the semiconductor substrate. The insulation material 1020 may be removed to allow for access to the contact pad 1027 from the backside. By passing the electrical connection from the BDTI to the frontside, both the BDTI and FDTI bias voltages can be applied at frontside contacts. FIG. 10B is the same as FIG. 10A except with region 1022 in FIG. 10A back filled with oxide-based material 1050 to embed the pad 1027.

FIG. 11A shows another process for producing FDTI structures, in accordance with some example embodiments. At process 1110, a semiconductor substrate 112 is etched to create deep trench isolation (DTI) structures 1114 with depth 1112. For example, some embodiments have a 3-5 micron depth 1112. The FDTI structures can be formed using photolithography and etching or other semiconductor processing technique. At process 1120, a sacrificial material with selectivity to silicon such as oxide-based material is deposited/grown inside to fill the trenches etched in 1110. At process 1130, a portion of the sacrificial material 1124 is removed at 1132 to reopen the trench.

FIG. 11B is a continuation of FIG. 11A. At 1140, oxide is grown or deposited on the inside walls 1144 of the reopened trench 1132 shown in 1130. At 1142, conductive material such as polysilicon, metal or other conductive material is used to fill the reopened trenches from front side. At 1150, other frontside processing is performed such as the frontside structures and devices detailed above in FIGS. 1, 8, and include forming photodiodes 1154, floating diffusion, transfer gates 1152, pixel transistors, and inter-layer dielectric 1156. At 1160, the backside 1162 of semiconductor substrate 112 is thinned to a desired thickness 1164. In some example embodiments, the backside 1162 is thinned so the structure thickness 1164 is about 3 microns. In some example embodiments, the backside 1162 is thinned so the structure thickness 1164 is about 5-6 microns.

FIG. 11C is a continuation of FIGS. 11A and 11B. At process 1170, the deep trenches are reopened by removing the sacrificial layer from the backside at 1172. At 1180, the high relative dielectric constant material is deposited/grown and oxide grown/deposited on the walls at 1182 and polysilicon (e.g., lightly doped) or other conductor filled in to produce BDTI structures. At 1190, a buffer layer 1193 can be added on the backside. Thereafter, a metal or composited metal grid 1194 is formed on the buffer layer 1193 defining a plurality of apertures aligning with corresponding photodiodes. Color (red, blue, green, or IR) filters 1192 can be deposited in the apertures and on the metal grid, and microlenses 1191 formed on the color filters to receive incoming light and direct incoming light to respective photodiode.

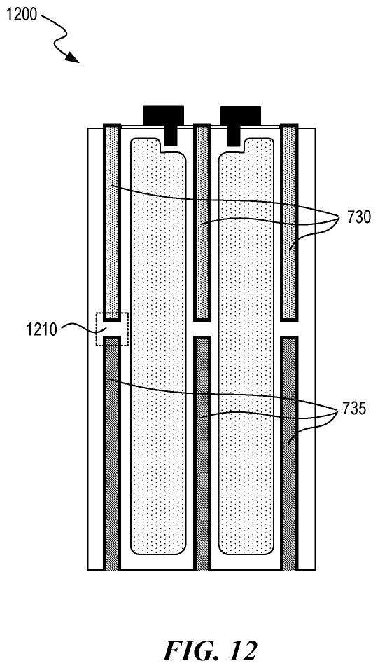

FIG. 12 shows photodiodes similar to FIG. 7 but with a gap between the FDTI structure 730 and BDTI structure 735. FIG. 12 includes a gap of substrate material sandwiched between the FDTI structure 730 and BDTI structure 735. That is, substrate material exists in between trenches of FDTI structure 730 and BDTI structure 735. Alternatively, substrate material is between liner oxide layer for FDTI structure 730 and liner oxide layer of BDTI structure 735. The gap 1210 can be created by controlling the depth of the FDTI structure and/or BDTI structure deep trenches when the trenches are etched. For example, the trench depths at 913 and 953 in FIGS. 9A and 9B can be reduced such that silicon substrate remains between the BDTI structure and FDTI structure trenches at 912 and 952.

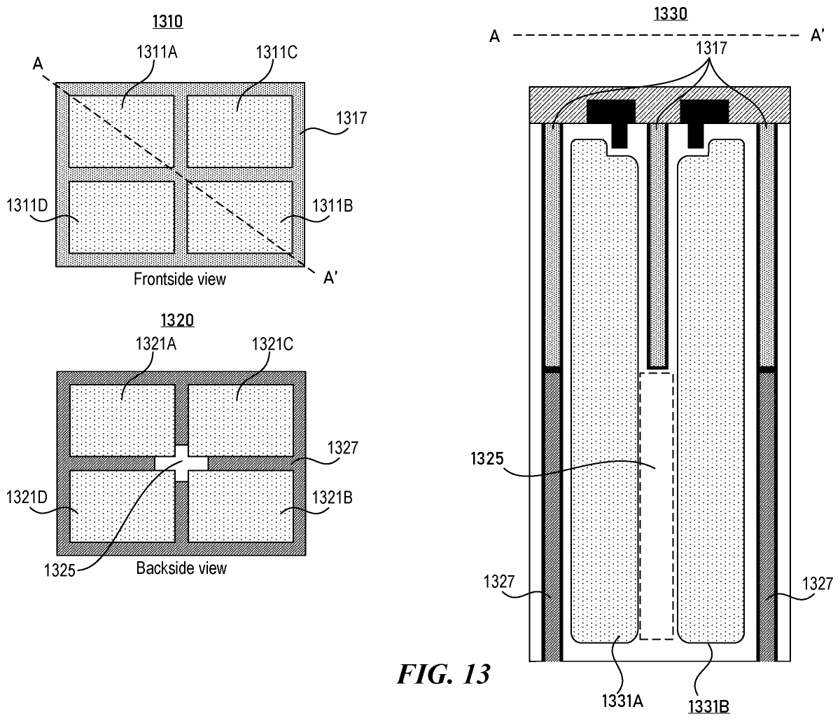

FIG. 13 shows various views of a four-cell pixel unit similar to FIG. 8 that is grouped as a pixel-cell unit included in an image sensor. The four-cell pixel unit includes four photodiodes 1331A, 1331B, 1331C, 1331D with the frontside view of photodiodes 1331A, 1331B, 1331C, 1331D shown at regions 1311A 1311B, 1311C, 1311D and backside view of photodiodes 1331A, 1331B, 1331C, 1331D shown at regions 1321A, 1321B, 1321C, 1321D. Note that just photodiodes 1331A, 1331B are visible in FIG. 13 at partial cross-sectional view 1330 along axis A-A′. Each of the four photodiodes 1331A, 1331B, 1331C, 1331D can each have separate transfer gates and floating diffusions (not shown) or one or more of the photodiodes and transfer gates can be coupled to a common floating diffusion (not shown). At 1310, a frontside view of the four-cell pixel unit is shown which includes the FDTI structure 1317. At 1320, a backside view of the four-cell pixel unit is shown which includes the BDTI structure 1327, and a region where no BDTI structure is present at 1325. At 1330, a cross-sectional view along axis A-A′ shows the region 1325 where the BDTI structure is omitted for the illustrated four-cell pixel unit. For example, as shown at 1330, there is no BDTI structure disposed in a region located at the center of four-cell pixel unit between photodiodes 1331A, 1331B. In the illustrated embodiments, there is no BDTI structure disposed in the region 1325 that is surrounded by photodiodes 1331A-1331D of the four-cell pixel unit. In some embodiments, the four-cell pixel unit may share a common color filter and a single microlens (not illustrated). Omitting a BDTI structure in the region 1325 of four-cell pixel unit can reduce light scattering in the center region to reduce crosstalk.

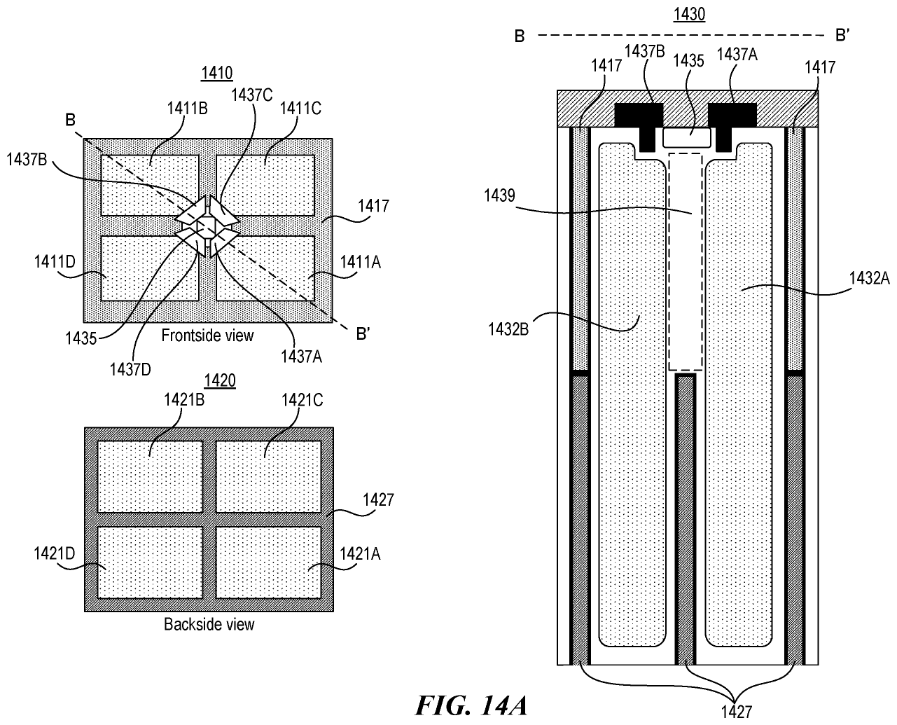

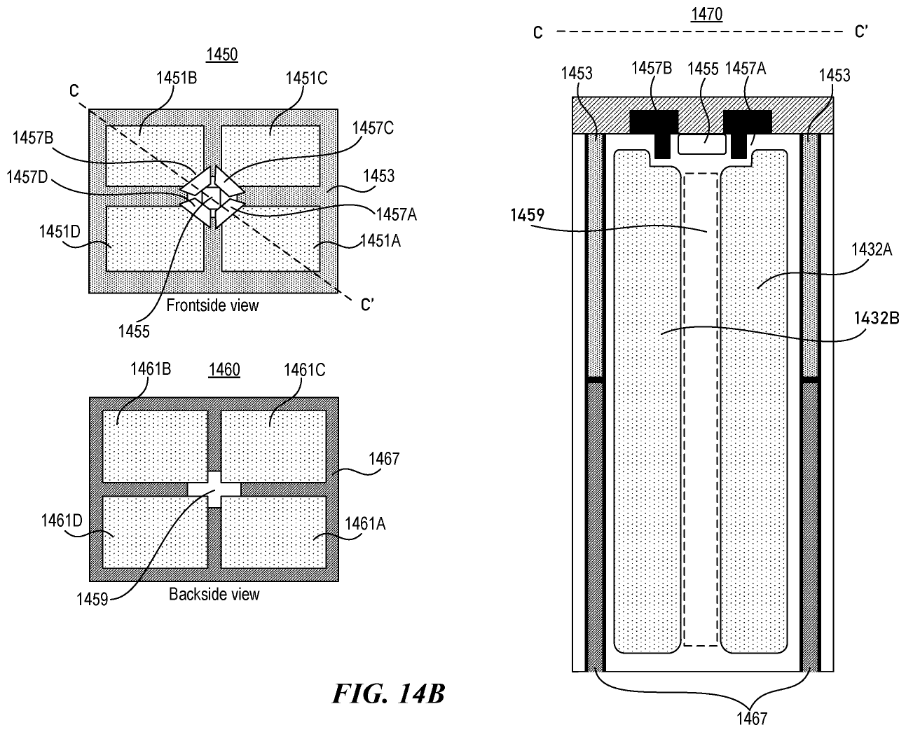

FIG. 14A shows various views of a four-cell pixel unit. The four-cell pixel unit includes four photodiodes 1432A, 1432B, 1432C, 1432D with the frontside view of photodiodes 1432A, 1432B, 1432C, 1432D shown at regions 1411A, 1411B, 1411C, 1411D and backside view of photodiodes 1432A, 1432B, 1432C, 1432D shown at region 1421A, 1421B, 1421C, 1421D. Note that only photodiodes 1432A, 1432B may be visible in FIG. 14A at 1430 which is a partial cross-sectional view along axis B-B′. At 1410, a frontside view of the four cells shows transfer gates 1437A-1437D connected between photodiodes 1432A, 1432B, 1432C, 1432D and floating diffusion 1435. Each of the transfer gates 1437A-1437D includes a planar gate and a vertical gate extending from the planar gate into the semiconductor substrate proximate to the respective photodiodes 1432A-1432D. Each of the photodiodes 1432A, 1432B, 1432C, 1432D has a portion that overlaps the vertical gate structure of the transfer gate 1437A, 1437B, 1437C, 1437D in a vertical direction. Each of the four photodiodes 1432A, 1432B, 1432C, 1432D is coupled to floating diffusion 1435 via a corresponding transfer gate for transferring accumulated photo-generated charges to the floating diffusion 1435. For example, photodiode 1432A is coupled to floating diffusion 1435 through transfer gate 1437A and when transfer gate 1437A turns on, the photo-generated charges in photodiode 1432A are transferred to the floating diffusion 1435. As shown in the depicted example, there is no FDTI structure 1417 present at the region 1439 (center) enabling the floating diffusion 1435 shared by four photodiodes 1432A, 1432B, 1432C, 1432D to be disposed in the center region of the four-cell pixel unit proximate to the frontside. At 1420, a backside view of the four-cell pixel unit is shown which includes BDTI structures 1427. At 1430, the cross-sectional view shows the transfer gates 1437A, 1437B disposed proximate to the frontside are coupled between floating diffusion 1435 and corresponding photodiodes 1432A and 1432B. Although not shown, there are also transfer gates 1437C, 1437D disposed proximate to the frontside coupled between floating diffusion 1435 and corresponding photodiodes 1432C and 1432D. The depicted example also illustrates that no FDTI structure 1417 is present in the region 1439 beneath the floating diffusion 1435 between adjacent photodiodes 1432A, 1432B, 1432C, 1432D. With no FDTI structure 1417 present in the region 1439 beneath the floating diffusion 1435 as shown, photodiodes 1432A, 1432B, 1432C, 1432D have no common biasing element (e.g., FDTI structure) between adjacent photodiodes 1432A, 1432B, 1432C, 1432D and thus the FDTIs have less effect on electric potential modification to nearby photodiodes 1432A, 1432B, 1432C, 1432D.

FIG. 14B shows various views of a four-cell pixel unit. The four-cell pixel unit includes four photodiodes 1432A, 1432B, 1432C, 1432D with the frontside view of photodiodes 1432A, 1432B, 1432C, 1432D shown at regions 1451A, 1451B, 1451C, 1451D and backside view of photodiodes 1432A,1432B, 1432C, 1432D shown at regions 1461A, 1461B, 1461C, 1461D.

Note that just photodiodes 1432A, 1432B are visible in FIG. 14B at 1470 which provides a partial cross-sectional view along axis C-C′. At 1450, a frontside view of the four cells is shown which shows transfer gates 1457A, 1457B, 1457C, 1457D connected between photodiodes 1432A, 1432B, 1432C, 1432D and floating diffusion 1455. Each of transfer gates 1457A-1457D includes a planar gate and a vertical gate extending from the planar gate into the semiconductor substrate proximate to the respective photodiodes 1432A-1432D. Each of photodiodes 1432A, 1432B, 1432C, 1432D has a portion that overlaps the vertical gate of the coupled transfer gate 1457A, 1457B, 1457C, 1457D in a vertical direction normal to the semiconductor substrate. Each of the four photodiodes 1432A, 1432B, 1432C, 1432D is coupled to floating diffusion 1455 via a corresponding transfer gate 1457A, 1457B, 1457C, 1457D to transfer charges to floating diffusion 1455. For example, photodiode 1432A is coupled to floating diffusion 1455 through transfer gate 1457A, and so on. As shown at 1450 FDTI structure 1453 surrounds the photodiodes 1432A, 1432B, 1432C, 1432D providing isolation between photodiodes 1432A, 1432B, 1432C, 1432D of the four-cell pixel unit and the photodiodes of adjacent four-cell pixel units. There is a region 1459 beneath the floating diffusion 1455 adjacent to photodiodes 1432A, 1432B, 1432C, 1432D where no FDTI structure 1453 is present. At 1460, a backside view of the four-cell unit is shown which includes the backside view of photodiodes 1432, 1432B, 1432C, 1432D and BDTI structure 1467, and region 1459 where no BDTI structure 1467 is present. That is, region 1459 is region without any deep trench isolation region. At 1470, a cross-sectional view shows the transfer gates 1457A/B coupled between floating diffusion 1455 and the photodiodes 1432A, 1432B. Although not shown, there are also transfer gates 1457C, 1457D disposed proximate to the frontside coupled between floating diffusion 1455 and corresponding photodiodes 1432C and 1432D. The depicted example also shows that neither FDTI structure 1453 nor BDTI structure 1467 is present in the region 1459 beneath the floating diffusion 1455 adjacent to photodiodes 1432A, 1432B, 1432C, 1432D. In some embodiments, the four-cell pixel unit may share a common color filter and a single microlens (not illustrated). Omitting the BDTI structure may have benefit of reducing light scattering in the center region improve on crosstalk.

The above description of illustrated examples of the disclosure, including what is described in the Abstract, is not intended to be exhaustive or to limit the disclosure to the precise forms disclosed. While specific examples of the disclosure are described herein for illustrative purposes, various modifications are possible within the scope of the disclosure, as those skilled in the relevant art will recognize.

These modifications can be made to the disclosure in light of the above detailed description. The terms used in the following claims should not be construed to limit the disclosure to the specific examples disclosed in the specification. Rather, the scope of the disclosure is to be determined entirely by the following claims, which are to be construed in accordance with established doctrines of claim interpretation.

1. A pixel cell, comprising:
a front deep trench isolation (FDTI) structure disposed in a semiconductor material and extending a first depth from a frontside of the semiconductor material into the semiconductor material, wherein the FDTI structure isolates a first region of the semiconductor material on a first side of the FDTI structure from a second region of the semiconductor material on a second side of the FDTI structure, wherein the FDTI structure includes a first conductive material coupled to receive a first bias voltage;
a back deep trench isolation (BDTI) structure disposed in the semiconductor material and extending a second depth from a backside of the semiconductor material into the semiconductor material, wherein the BDTI structure isolates the first region of the semiconductor material on a first side of the BDTI structure from the second region of the semiconductor material on a second side of the BDTI structure, wherein the BDTI structure includes a second conductive material coupled to receive a second bias voltage, and wherein the FDTI structure and BDTI structure are at least partially aligned in a depthwise direction of the semiconductor material; and
a photodiode disposed in the first region of the semiconductor material to accumulate image charge, wherein the photodiode extends along the depthwise direction and is disposed proximate to at least a portion of the FDTI structure and a portion of the BDTI structure.

2. The pixel cell of claim 1, further comprising a first electrically isolating material disposed between the first conductive material and the semiconductor material, and a second electrically isolating material disposed between the second conductive material and the semiconductor material.

3. The pixel cell of claim 1, wherein the FDTI structure is vertically aligned with the BDTI structure.

4. The pixel cell of claim 1, wherein the first bias voltage operates to modulate a first electric potential of a first photodiode region proximate to the frontside of the semiconductor material, and the second bias voltage operates to modulate a second electric potential of a second photodiode region proximate to the backside of the semiconductor material.

5. The pixel cell of claim 1, wherein the first conductive material and the second conductive material are of different material.

6. The pixel cell of claim 1 wherein the FDTI structure is in direct contact with the BDTI structure.

7. The pixel cell of claim 6, wherein the first conductive material and the second conductive material are electrically isolated.

8. The pixel cell of claim 1, wherein the FDTI structure is vertically aligned with and spaced apart from the BDTI structure.

9. An imaging system, comprising:
a pixel array having a plurality of pixel cells, wherein each of the plurality of pixel cells comprises:
a photodiode disposed in an epitaxial layer in a first region of a semiconductor material to accumulate image charge;
a front deep trench isolation (FDTI) structure disposed in a semiconductor material and extending a first depth from a frontside of the semiconductor material into the semiconductor material, wherein the FDTI structure isolates the first region of the semiconductor material on a first side of the FDTI structure from a second region of the semiconductor material on a second side of the FDTI structure, wherein the FDTI structure includes a first conductive material coupled to receive a first bias voltage; and
a back deep trench isolation (BDTI) structure disposed in the semiconductor material and extending a second depth from a backside of the semiconductor material into the semiconductor material, wherein the BDTI structure isolates the first region of the semiconductor material on a first side of the BDTI structure from the second region of the semiconductor material on a second side of the BDTI structure, wherein the BDTI structure includes a second conductive material coupled to receive a second bias voltage,
wherein the FDTI and BDTI structures are at least partially aligned in a direction from the frontside to the backside of the semiconductor material, and wherein each photodiode lies along the direction and proximate to at least a portion of the FDTI structure and a portion of the BDTI structure;
control circuitry coupled to the pixel array to control operation of the pixel array; and
readout circuitry coupled to the pixel array to readout image data from the plurality of pixel cells.

10. The imaging system of claim 9, wherein the second conductive material of the BDTI structure is connected to a contact pad through a metal interconnect in a first metal layer proximate to the frontside of the semiconductor substrate.

11. The imaging system of claim 10, wherein the BDTI structure is one of a plurality of BDTI structures forming a BDTI structure grid, and wherein at least one of the plurality of BDTI structures is connected to the contact pad.

12. The imaging system of claim 11, wherein the second conductive material of each of the plurality of BDTI structures are electrically connected together at the contact pad proximate to the backside of the semiconductor material.

13. The imaging system of claim 10, further comprising an insulation material disposed between the contact pad and the semiconductor material.

14. The imaging system of claim 9, further comprising:
a first center region disposed between the photodiodes of the plurality of pixel cells and extending the first depth from the frontside of the semiconductor material; and
a second center region disposed between the photodiodes of the plurality of pixel cells and extending the second depth from the backside of the semiconductor material,
wherein the FDTI structure is disposed in the first center region, and
wherein the BDTI structure is not disposed in the second center region.

15. The imaging system of claim 9, further comprising:
a first center region disposed between the photodiodes of the plurality of pixel cells and extending the first depth from the frontside of the semiconductor material; and
a second center region disposed between the photodiodes of the plurality of pixel cells and extending the second depth from the backside of the semiconductor material,
wherein the FDTI structure is not disposed in the first center region, and
wherein the BDTI structure is disposed in the second center region.

16. The imaging system of claim 9, further comprising:
a first center region disposed between the photodiodes of the plurality of pixel cells and extending the first depth from the frontside of the semiconductor material; and
a second center region disposed between the photodiodes of the plurality of pixel cells and extending the second depth from the backside of the semiconductor material,
wherein the FDTI structure is not disposed in the first center region, and
wherein the BDTI structure is not disposed in the second center region.

17. The imaging system of claim 9, wherein the control circuitry operatively applies the first bias voltage to the first conductive material of FDTI structure to modulate a first electric potential of a first photodiode region of the photodiode proximate to the frontside of the semiconductor material, and the second bias voltage to the second conductive material of BDTI structure to modulate a second electric potential of a second photodiode region of the photodiode proximate to the backside of the semiconductor material.

18. The imaging system of claim 9, wherein the FDTI structure is vertically aligned and in direct contact with the BDTI structure.

19. The imaging system of claim 9, wherein the FDTI structure is vertically aligned with and spaced apart from the BDTI structure.

20. The imaging system of claim 9, wherein one or more of the first conductive material or the second conductive material comprises a doped polysilicon or a metal.

21. A method of reducing image lag for an image sensor, comprising:
applying, by a control circuit of the image sensor, during an integration period, a first bias voltage to a first conductive material of a frontside deep trench isolation (FDTI) structure disposed on a frontside of a semiconductor material having a photodiode, wherein the FDTI structure extends to a first depth into the semiconductor material from the frontside, and is disposed in proximity to a first portion of the photodiode;
applying, by the control circuit, during the integration period, a second bias voltage to a second conductive material of te-a backside deep trench isolation (BDTI) structure disposed on a backside of the semiconductor material and extending to a second depth into the semiconductor material from the backside opposite to the frontside, wherein the BDTI structure is vertically aligned with the FDTI structure and in proximity to a second portion of the photodiode;
applying, by the control circuit, during a charge transfer period of the photodiode, a third bias voltage to the first conductive material and a fourth bias voltage to the second conductive material after the integration period.

22. The method of claim 21, wherein the first and second bias voltages are selected such as that an electric potential curve of the photodiode has a positive slope from the backside toward the frontside of the semiconductor substrate. (Original)

23. The method of claim 22, wherein the first, second, third, and fourth bias voltages are selected based on a pinning voltage of the photodiode or a depletion voltage of the photodiode.

24. A process for producing a pixel cell, comprising:
forming a first and second deep trenches proximate to a photodiode in a frontside of the semiconductor material;
forming a first insulating layer lining first sidewalls and first bottom surfaces of the first and second deep trenches;
depositing a first conductive material into the first and second deep trenches, wherein the first insulating layer lies between the first conductive material and the first sidewalls and the first bottom surfaces of the first and second deep trenches, wherein the first insulating layer on the first sidewalls and the first bottom surfaces of the first and second deep trenches electrically isolate the first conductive material in the first and second deep trenches from the semiconductor material.

25. The process of claim 24, further comprising:
forming third and fourth deep trenches proximate to the photodiode in a backside of a semiconductor material, wherein the backside is opposite to the frontside;
forming a second insulating layer on second sidewalls and second bottom surfaces of the third and fourth deep trenches; and
depositing a second conductive material into the third and fourth deep trenches, wherein the second insulating layer lies between the second conductive material and the second sidewalls and second bottom surfaces of the third and fourth deep trenches, wherein the first and second insulating layers electrically isolate the second conductive material in third and fourth deep trenches from the semiconductor material,
wherein the third deep trench is vertically aligned with the first deep trench, and the fourth deep trench is vertically aligned with the second deep trench.

26. The process of claim 25, wherein the photodiode extends substantially from the frontside of the semiconductor material along the first and second deep trenches to the backside of the semiconductor material along the third and fourth deep trenches.

27. The process of claim 26, further comprising:
depositing, after the forming the first insulating layer and before depositing the first conductive material, a sacrificial layer filling the first and second deep trenches;
removing, after the depositing the sacrificial layer, first portions of the sacrificial layer from the first and second trenches to a predetermined depth;
removing, after depositing the first conductive material, second portions of the sacrificial layer from the first and second trenches;
forming, after removing the second portions of the sacrificial layer, a second insulating layer on second sidewalls and second bottom surfaces of the deep trenches formed by the removing the second portions; and
depositing, after the removing the second portions of the sacrificial layer, a second conductive material into the removed second portions, wherein the second insulating layer lies between the second conductive material and the second sidewalls and second bottom surfaces of the third and fourth deep trenches.

28. The process of claim 27, wherein each of the first conductive material and the second conductive material comprises a metal or a polysilicon material.
